(19) United States
(12) Patent Application Publication
(10) Pub. No.: US 2026/0032371 A1
(43) Pub. Date: Jan. 29, 2026

(54) HEAT MANAGEMENT FOR AUDIO ELECTRONICS

(71) Applicant: Shure Acquisition Holdings, Inc., Niles, IL (US)

(72) Inventor: Jacob Cramer, Chicago, IL (US)

(73) Assignee: Shure Acquisition Holdings, Inc., Niles, IL (US)

(21) Appl. No.: 19/276,265

(22) Filed: Jul. 22, 2025

Related U.S. Application Data
(60) Provisional application No. 63/675,812, filed on Jul. 26, 2024.

(51) Int. Cl. H04R 1/08; H04R 1/04; H05K 7/20

(52) U.S. Cl. CPC H04R 1/086; H04R 1/04; H05K 7/2039

(57) ABSTRACT

Thermal management assemblies are described that may be used to reduce the operating temperature of electronics and/or electronic components, such as audio electronic components that may be used as part of active microphone configurations, for example. A heat spreader may be implemented within a microphone assembly for instance, which may be used for active microphone operation. The microphone assembly may additionally include one or more microphones, various audio electronic components, a chassis, and a grill cover that is used to allow sound to pass into the microphone assembly. The heat spreader may function to provide a heat path from the audio electronic components to the grill cover, which may function as a heat sink. The heat spreader may enable thermal management of the audio electronic components for a variety of mounting configurations and grill cover designs.

### CROSS-REFERENCE TO RELATED APPLICATIONS

This application claims priority to U.S. provisional application no. 63/675,812, filed on Jul. 26, 2024, the contents of which are incorporated herein by reference in their entirety.

### FIELD

Aspects described herein generally relate to thermal management for audio electronics and, more particularly, to the implementation of various heat spreader assemblies for audio electronics that facilitate the use of a grill cover as a heat sink.

### BACKGROUND

Audio systems often implement a variety of audio electronic components such as microphones, which function to transduce sound into electrical signals that may then be provided to an accompanying speaker to produce sound. The electrical signals may be provided in this manner via a direct connection to an output speaker or, alternatively, the conversion of the transduced electrical signals to digital data may be transmitted to a network and/or various components of a sound distribution system. In either case, microphones may operate in accordance with passive or active configurations. Passive configurations do not utilize electricity for their operation. However, as the use of audio sound distribution has evolved, it has been recognized that for at least some applications, active microphone configurations may provide much better performance. This is particularly true for active microphone arrays, which enable desirable qualities such as active audio beam forming.

Such active microphone configurations typically implement active (e.g. powered) elements such as a power supply, amplifiers, pre-amplifiers, etc., which may be implemented as various types of audio integrated circuits (ICs). However, the use of such active microphone configurations results in the active elements generating a significant amount of heat. For example, during operation the temperature of the various audio ICs that may be used in conjunction with the microphone elements of an active microphone configuration may significantly increase and, if this temperature increase is not mitigated, may result in IC failure, malfunctions, a reduction in operating product life, and/or performance degradation. Thus, thermal management of audio electronic components such as, for example, audio ICs implemented for active microphone configurations, may be an important operating specification that needs to be addressed. However, current solutions for managing heat buildup for active audio configurations have thus far been inadequate.

### SUMMARY

The following presents a simplified summary of the disclosure to provide a basic understanding of some aspects of the disclosure. This summary is not an extensive overview of the disclosure. It is not intended to identify key or critical elements of the disclosure or to delineate the scope of the disclosure. The following summary merely presents some concepts of the disclosure in a simplified form as a prelude to the more detailed description provided below.

Again, conventional thermal management for audio components, which may include audio components used in active microphone configurations, for example, has been inadequate. For instance, for many audio configurations, this issue is complicated by the particular audio assembly often being isolated with respect to thermal couplings to external heat paths. For instance, a microphone assembly may only have minimal electrical connections and/or may not be coupled to external components that provide sufficient thermal conductivity to function as a heat path to wick heat away from the audio electronic components. As another example, a microphone assembly may have insufficient surface area to convect heat out of surfaces to ensure that proper thermal management is achieved.

For instance, a microphone assembly may be implemented as a freestanding or mounted component that may be positioned within an environment in which it is used. That is, to provide a more aesthetically pleasing and unobtrusive product, microphone assemblies may be mounted to and/or installed in walls, the ceiling, placed on a table or shelf, etc. Additionally, microphone assemblies that use active microphone configurations may be connected to a single input/output (I/O) port (e.g. an Ethernet cable connection) that provides power, facilitates the receipt of control data, and allows for other types of data communications such as the transmission of digitized audio data that may be output by the active microphone configuration. As a result, to simplify installation and/or reduce costs, the I/O port and the mounting surface may be the only external connections to the microphone assembly. Each of these physical connections, however, may be generally insufficient to provide a heat path for the audio electronic components given the low thermal mass of the I/O port (e.g. a single Ethernet connector) and/or the low thermal conductivity of the coupled mounting surface (e.g. a ceiling tile, a wood conference table, etc.).

The embodiments described herein improve upon the thermal management of any suitable type of heat source (e.g. audio electronic components) that may be implemented as part of any suitable type of assembly, such as microphone assemblies for example, which may be implemented as part of an active microphone configuration. To do so, the embodiments as described herein provide assemblies that may be mountable to any suitable surface (e.g. a ceiling or wall) or freestanding. The assemblies may comprise one or more chassis components and contain one or more microphones and accompanying audio electronic components to support active microphone configurations, which may form part of a printed circuit board (PCB) assembly. The assemblies may also comprise a grill cover, which may be thermally-conductive and have openings and/or perforations to allow for sound to pass into the assembly and to be received by the various microphones. The assemblies may also comprise a heat spreader that may be coupled to the chassis components and to the grill cover. The heat spreader may also be thermally conductive, and may have a size and shape such that the various heat sources (e.g. the audio electronic components) within the assembly may be in thermal contact with specific portions of the heat spreader when assembled. The heat spreader thus functions to provide a heat path between the heat source(s) of the assembly and the grill cover, thereby wicking heat away from the heat sources to cool them during operation.

As described in more detail herein, this application sets forth methods, apparatuses, and systems for improving the thermal management of audio electronic components to ensure safety and good audio performance.

An example microphone assembly may comprise a chassis; a heat spreader coupled to the chassis and thermally coupled to a heat source contained within the microphone assembly; and a thermally-conductive grill cover coupled to the heat spreader, wherein the heat spreader is configured to provide a heat path from the heat source to the thermally-conductive grill cover to enable the thermally-conductive grill cover to function as a heat sink for the heat source.

An example microphone assembly may comprise a chassis; a microphone; a thermally-conductive heat spreader configured to be thermally coupled to an audio integrated circuit (IC) associated with the microphone; and a thermally-conductive grill cover configured to be thermally coupled to the thermally-conductive heat spreader, wherein the thermally-conductive heat spreader is configured to provide a heat path from the audio IC to the thermally-conductive grill cover to enable the thermally-conductive grill cover to function as a heat sink for the audio IC.

An example microphone assembly may comprise a grill cover assembly including a thermally-conductive upper chassis and a thermally-conductive grill cover; a lower chassis; and a heat spreader thermally coupled to the grill cover assembly and thermally coupled to a heat source contained within the microphone assembly, wherein the heat spreader is configured to provide a heat path from the heat source to the grill cover assembly to enable the thermally-conductive grill cover to function as a heat sink for the heat source.

It is noted that although the embodiments may be described herein in terms of a microphone assembly, this is by way of example and not limitation. The thermal management functionality as discussed in further detail herein, which includes the use of a grill cover, may be implemented in accordance with any suitable components and/or assemblies. This may include both audio and non-audio configurations that may benefit from the use of a grill cover as a heat sink as discussed herein. As one example, the embodiments described herein may be extended to speaker assemblies that also utilize thermally-conductive grill covers, and which may also comprise active audio components such as amplifiers and/or speaker drivers as heat sources.

These as well as other novel advantages, details, examples, features and objects of the present disclosure will be apparent to those skilled in the art from following the detailed description, the attached claims and accompanying drawings, listed herein, which are useful in explaining the concepts discussed herein.

### BRIEF DESCRIPTION OF THE DRAWINGS

Some features are shown by way of example, and not by limitation, in the accompanying drawings. In the drawings, like numerals reference similar elements.

FIG. 1 illustrates a block diagram of an example audio system that may be used to implement one or more illustrative aspects described herein.

FIGS. 2A-2F illustrate example views of a microphone assembly that may be used to implement one or more illustrative aspects described herein.

FIG. 2G illustrates an example thermal map of the microphone assembly as shown in FIGS. 2A-2F during operation without a heat pipe, which may be used to implement one or more illustrative aspects described herein.

FIGS. 3A-3C illustrate example views of the microphone assembly as shown in FIGS. 2A-2G comprising a heat pipe, which may be used to implement one or more illustrative aspects described herein.

FIGS. 3D-3E illustrate example thermal maps of the microphone assembly as shown in FIGS. 2A-2G during operation without a heat pipe, which may be used to implement one or more illustrative aspects described herein.

FIGS. 3F-3G illustrate example thermal maps of the microphone assembly as shown in FIGS. 2A-2G comprising a heat pipe, which may be used to implement one or more illustrative aspects described herein.

FIGS. 4A-4E illustrate example views of another microphone assembly that may be used to implement one or more illustrative aspects described herein.

FIG. 4F illustrates an example thermal map of the microphone assembly as shown in FIGS. 4A-4E, which may be used to implement one or more illustrative aspects described herein.

FIG. 4G illustrates an example thermal conductivity map of the microphone assembly as shown in FIGS. 4A-4E, which may be used to implement one or more illustrative aspects described herein.

FIGS. 5A-5K illustrate example views of a further microphone assembly that may be used to implement one or more illustrative aspects described herein.

FIG. 6 illustrates a block diagram showing example details of the various components that may be part of a microphone assembly in accordance with one or more illustrative aspects described herein.

FIG. 7 illustrates an example flow chart of a process that may be performed to assemble the microphone assembly in accordance with one or more illustrative aspects described herein.

### DETAILED DESCRIPTION

In the following description of the various examples, reference is made to the accompanying drawings, which form a part hereof, and in which is shown by way of illustration various examples in which aspects may be practiced. References to “embodiment,” “example,” “aspect,” and the like indicate that the embodiment(s) or example(s) of the disclosure so described may include particular features, structures, or characteristics, but not every embodiment or example necessarily includes the particular features, structures, or characteristics. Further, it is contemplated that certain embodiments or examples may have some, all, or none of the features described for other examples. And it is to be understood that other embodiments and examples may be utilized and structural and functional modifications may be made without departing from the scope of the present disclosure.

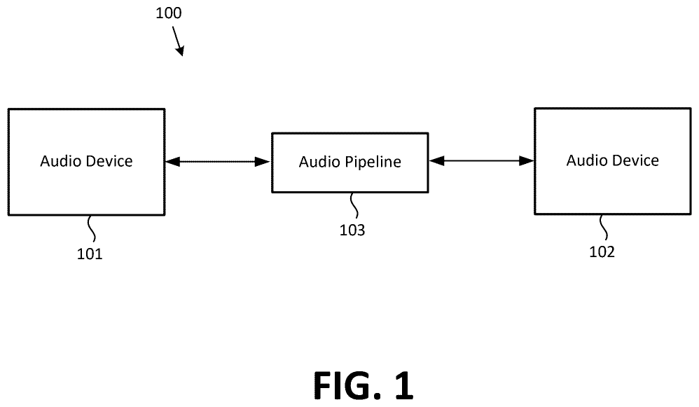

FIG. 1 illustrates a block diagram of an example audio system that may be used to implement one or more illustrative aspects described herein. The audio system 100 may comprise a plurality of audio devices, such as audio device 101 and audio device 102. The plurality of audio devices may be communicatively coupled to one another via an audio pipeline 103, which may comprise any suitable type of medium. For instance, the audio pipeline 103 may comprise one or more hardware and/or software components configured to communicate with one or more components of a microphone assembly, as discussed in further detail herein. The audio pipeline 103 may couple power and control signals to the audio device 101, which may be implemented as a microphone assembly, for example. The audio pipeline 103 may additionally couple digitized output signals from the audio device 101, which may be implemented as a microphone assembly for instance, to the audio device 102, which may be implemented as a speaker, for example.

The audio pipeline 103 may be implemented as part of a device that may be co-located in the same environment as the audio devices 101, 102. In this scenario, the audio pipeline 103 may be implemented as part of any suitable type of audio device, which may interface with the audio devices 101, 102 via any suitable configuration of wired and/or wireless links, ports, interfaces, etc. For instance, the audio pipeline 103 may be implemented as part of an audio device in which the audio devices 101, 102 may be connected as part of the audio system 100, and which may be used in any suitable environment in which the audio devices 101, 102 may also be used. The audio devices 101, 102 and the audio pipeline 103 may be co-located, or any combination of the audio devices 101, 102 and the audio pipeline 103 may be co-located or located remote from one another. The audio pipeline 103 may be configured to couple the audio signals received via the audio device 101 to the audio device 102 and, in doing so, to perform any suitable type of audio processing such as digital signal processing (DSP), filtering, etc. As another example, the audio pipeline 103 may be implemented as part of a communication network (e.g., a cloud computing device, a server, etc.) and/or may be coupled to the audio devices 101, 102 via such a communication network.

The audio devices 101, 102 may comprise any suitable type of device that may be capable of sending, receiving, and/or processing (e.g., modifying, storing, and/or operating in response to) audio. Non-limiting examples of audio devices include devices that are, or that include, microphones, speakers, conferencing equipment, audio recorders, personal computers, servers, display devices (e.g., television or computer displays), networking devices, audio mixers, and musical instruments. For example, the audio device 101 may comprise a microphone assembly as discussed herein. As another example, the audio device 101 may comprise one or more audio electronic components of the microphone assembly as further discussed herein, such as one or more microphones and/or one or more audio electronic components associated with such microphones. As an additional example, the audio device 102 may be or otherwise include a speaker. Each of the audio devices 101, 102 may comprise any suitable number and/or type of individual components, e.g., several microphones, speakers, etc., interconnected via the audio pipeline 103, and thus the audio system 100 may comprise a multiple-input, multiple-output audio system in such cases.

Audio data that may be generated based on sound detected by a microphone may be transmitted by the audio device 101 as one or more audio signals, via the audio pipeline 103, to at least the audio device 102. The audio device 102 may accordingly cause its speaker to generate sound based on the received audio data. This is but one example—as another example, each of the audio devices 101 and 102 may include both a microphone and a speaker. As a further example, the audio device 101 may include a microphone and the audio device 102 may include a computing device configured to store audio data received from the audio device 101. As a further example, the audio devices 101 and 102 may each be elements of a teleconferencing or videoconferencing system. As a further example, the audio devices 101 and 102 may each be elements of a public address system.

When implemented as part of the audio pipeline 103, the communication network may be any suitable type of network (including a simple connection between audio devices 101, 102) using any suitable number and/or type of protocols. For example, the communication network may utilize Internet Protocol (IP) to carry data such as audio data in IP datagrams. The communication network may send such IP datagrams using a particular data link layer protocol, such as Ethernet. This combination of IP and Ethernet is known as IP Over Ethernet (IPoE), in which data (such as audio data) is placed in IP datagrams, and the IP datagrams may be encapsulated in Ethernet frames. The term “packet” will be used herein to include various organized groupings of data, such as but not limited to datagrams (for example, User Data Protocol (UDP) datagrams) and frames.

Each of the audio devices 101, 102 may therefore be configured to send, via the audio pipeline 103, data to one or more other audio devices. Each of the audio devices 101, 102 may further be configured to receive, via the audio pipeline 103, data from one or more other audio devices. Any of the audio devices may be configured to both send and receive data, to exclusively send data, or to exclusively receive data. For example, the audio device 101 may be configured to send and/or receive data via the audio pipeline 103 to and/or from the audio device 102, and the audio device 102 may be configured to send and/or receive data via the audio pipeline 103 to and/or from the audio device 101. The data sent between the audio devices may include audio data, video data, communication control data, system control data, audio processing parameter data, and/or any other suitable types of data.

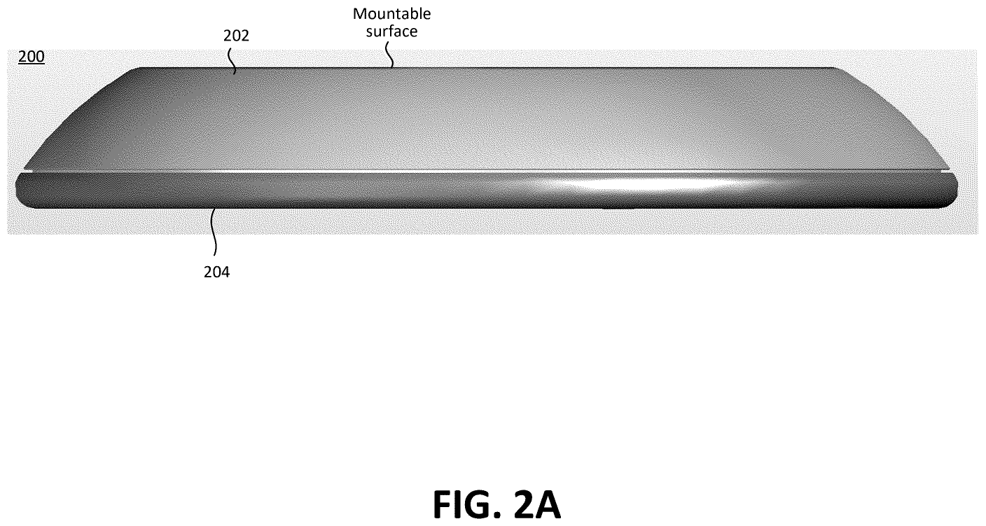

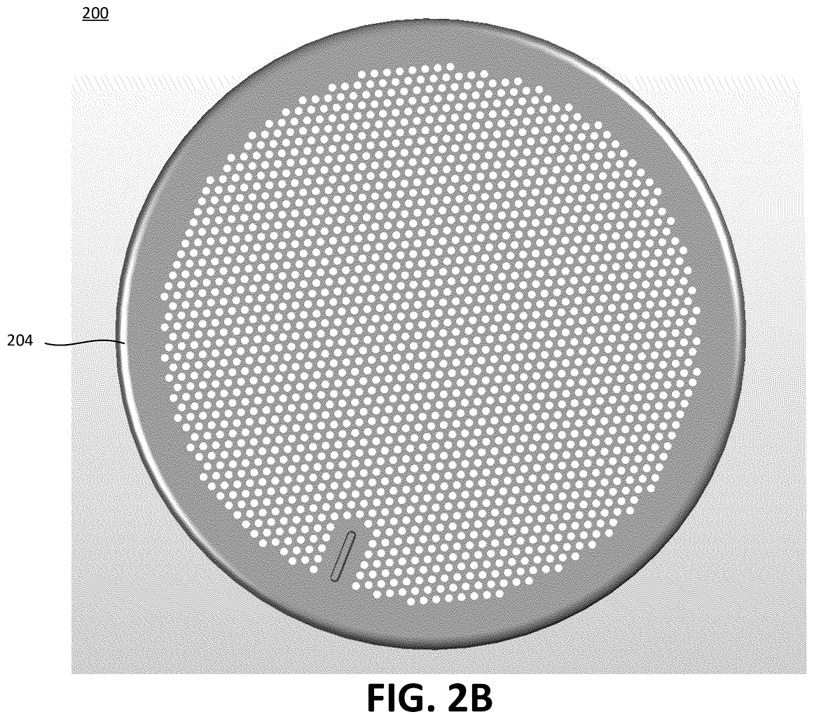

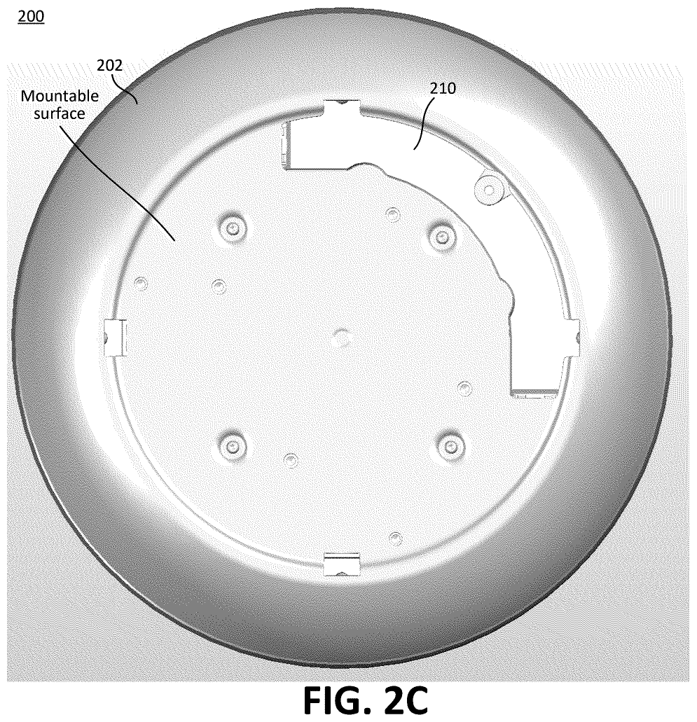

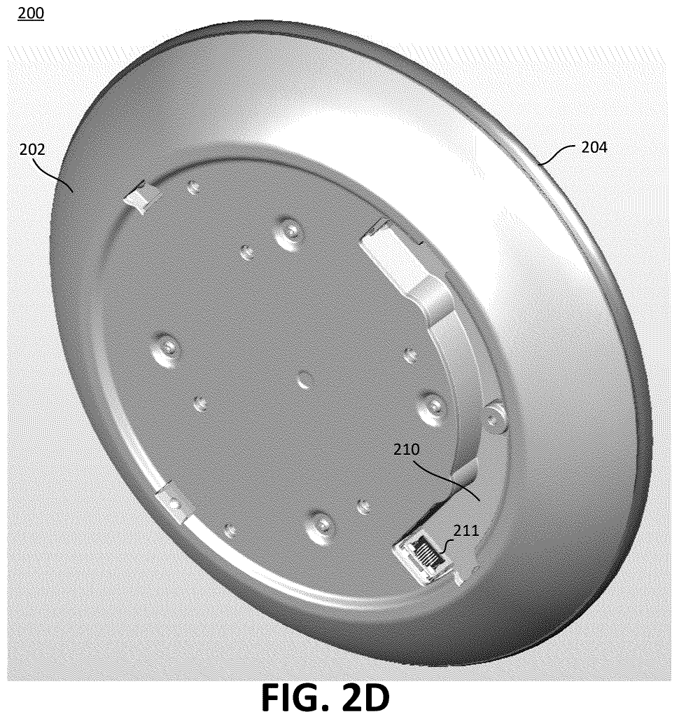

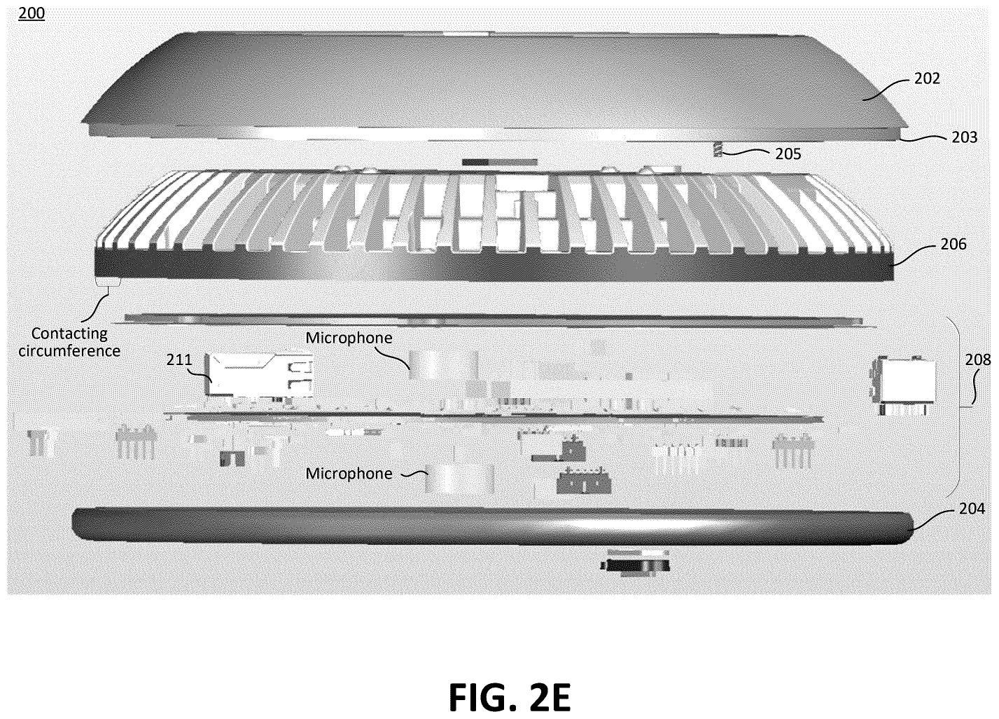

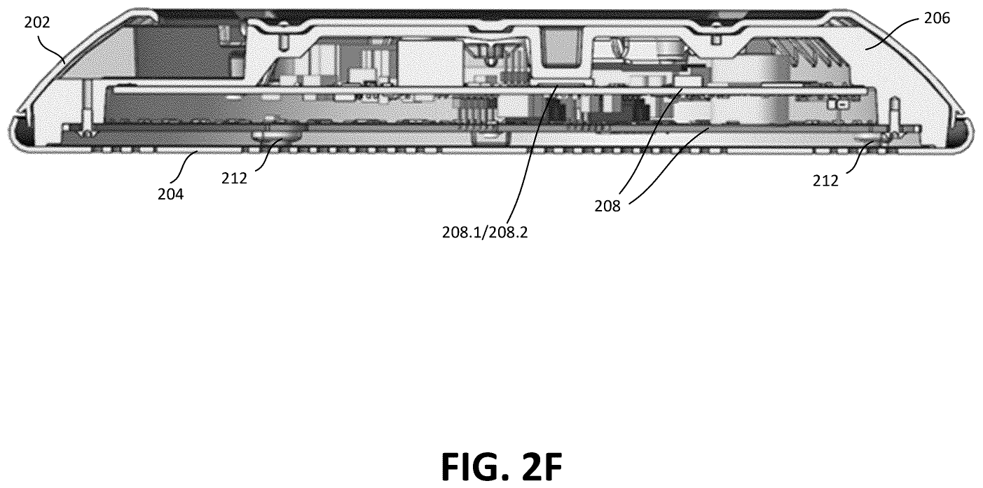

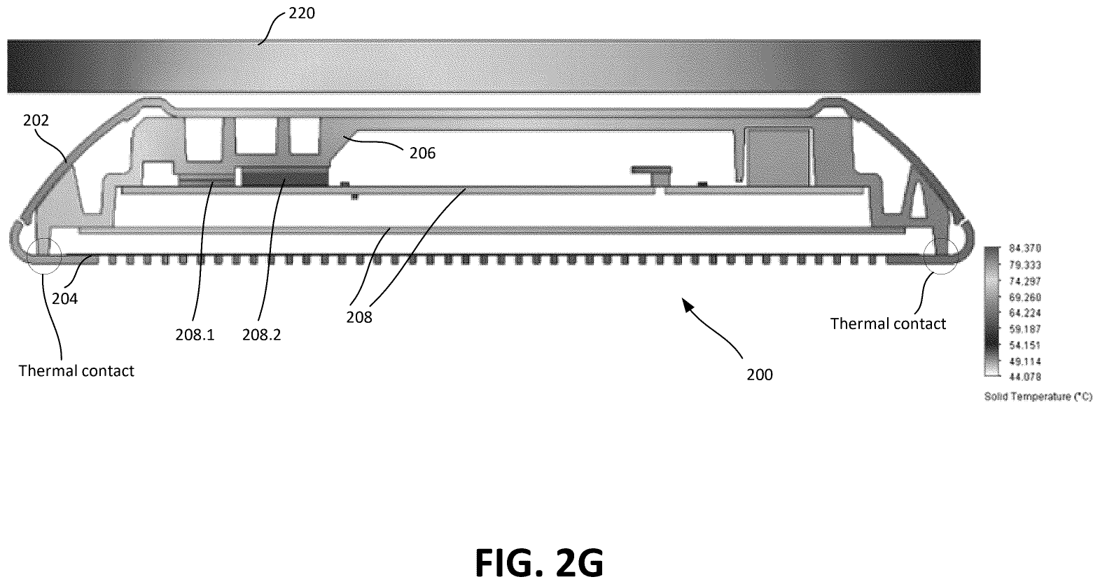

FIGS. 2A-2F illustrate example views of a microphone assembly that may be used to implement one or more illustrative aspects described herein. Additionally, FIG. 2G illustrates an example thermal map of the microphone assembly as shown in FIGS. 2A-2F during operation without a heat pipe, which may be used to implement one or more illustrative aspects described herein. The view as shown for the thermal map in FIG. 2G may correspond to that of the microphone assembly as shown in FIG. 2F. FIGS. 2A-2G may represent various views of the microphone assembly 200 as discussed in further detail herein, with the various components being identified via like reference numerals as shown.

The microphone assembly 200 as shown and discussed herein with respect to FIGS. 2A-2G is provided by way of example and not limitation. Additionally, the various components are illustrated for ease of explanation, and it will be understood that any or all of these components may have an alternative size, shape, and/or be comprised of alternate materials than those described herein. The microphone assembly 200 as shown and discussed herein with respect to FIGS. 2A-2G may also include additional, fewer, or alternate components than those described herein.

The microphone assembly 200 is shown in FIG. 2A in a side view, and includes a chassis 202 and a grill cover 204. The chassis 202 may comprise any suitable type of material based upon the particular application. For instance, the chassis 202 may comprise a thermally-conductive material such as a metal (e.g. aluminum, cast aluminum, zinc alloys, steel, stainless steel, etc.). Alternatively, the chassis 202 may comprise a thermal insulator such as a polymer, for example. The selection of the material for the chassis 202 may be based upon design considerations such as thermal efficiency, cost, a preference for the surface temperature range of the chassis 202 during operation, etc.

The microphone assembly 200 also comprises a grill cover 204, which may comprise a thermally-conductive material such as a metal (e.g. aluminum, cast aluminum, zinc alloys, steel, stainless steel, etc.) for instance. The microphone assembly 200 as shown in FIGS. 2A-2G may be implemented as a surface-mountable assembly, and thus the chassis 202 may comprise a mountable surface as shown in FIG. 2A, which may be configured to be mounted to any suitable surface such as a ceiling, a wall, set on a flat surface such as a table, etc. When implemented as a ceiling-mounted microphone assembly, the mounting surface of the chassis 202 may be adjacent and coupled to a ceiling surface such as a ceiling tile, drywall, etc. Thus, the orientation as shown in FIG. 2A may correspond to the microphone assembly 200 being mounted to a ceiling, with the grill cover 204 being disposed opposite to the ceiling surface, e.g. facing “downwards” into an environment to pick up the sounds in that environment. This orientation is shown in further detail in FIGS. 2F and 2G, with FIG. 2G also illustrating a ceiling 220. When set on a flat surface, the mounting surface may be adjacent to and abut the flat surface upon which the microphone assembly 200 is placed. In any event, the grill cover 204 may be disposed on a side of the microphone assembly 200 that is opposite to the mountable surface of the chassis 202, as shown in FIG. 2A.

FIG. 2B illustrates a top-down view of the microphone assembly 200 from the side of the grill cover 204. Thus, the grill cover 204 is shown in greater detail in FIG. 2B, which comprises perforations configured to enable sound to pass into the microphone assembly 200. The perforations are shown in FIG. 2B as regularly spaced holes in the grill cover 204, although this is by way of example and not limitation. The grill cover 204 may comprise any suitable number of perforations having any suitable size and shape. Alternatively, the grill cover 204 may comprise non-uniform perforations and/or other openings to facilitate the passage of sound into the microphone assembly 200. This may include, for instance, ducts or other passages besides or in addition to such perforations. As another example, the grill cover 204 may have various shapes that may impact the thermal efficiency of the grill cover 204 as a heat sink. For example, the grill cover 204 is shown as having a flat surface in FIG. 2A, but may alternatively have a convex surface to increase the surface area to improve its efficiency as a heat sink.

FIG. 2C illustrates a top-down view of the microphone assembly 200 from the side of the mounting surface of the chassis 202. Thus, the chassis 202 is shown in greater detail in FIG. 2C and includes a channel 210 that may be configured to accept any suitable type of cable, wiring, etc., which may include a connector configured to be coupled to a connector 211 of the microphone assembly 200, as shown in further detail in FIG. 2D. The connector 211 is shown in FIG. 2D as an Ethernet connector by way of example and not limitation, although the connector 211 may include any suitable number of pins and/or comprise any suitable type of connector. The connector 211 may thus, for example, be coupled to a mating connector of an external cable that provides power (e.g. power over Ethernet (PoE)), control data, facilitates the communication of digitized audio data transmitted by the various audio electronic components of the microphone assembly 200, etc., as discussed herein.

FIG. 2E illustrates an exploded view of the microphone assembly in the same side view orientation as shown in FIG. 2A. As shown in FIG. 2E, the microphone assembly 200 comprises additional components that may be housed within the chassis 202, which include a heat spreader 206 and a PCB assembly 208. The PCB assembly 208 may comprise any suitable number of PCBs, each occupying a separate layer of the PCB assembly 208, with two being shown in FIG. 2E by way of example and not limitation. Each of the PCBs of the PCB assembly 208 may comprise any suitable number of audio electronic components and/or other components depending upon the particular implementation and application. For example, the audio electronic components as shown in FIG. 2E may comprise one or more microphones, one or more integrated circuits (ICs) such as audio ICs and/or power management ICs for example, other suitable types of circuits and/or circuit components, connectors (such as the connector 211), etc. Thus, the PCB assembly 208 may comprise the PCBs as well as any suitable components disposed on or otherwise coupled to the PCBs, as shown in FIG. 2E.

Any components of the PCB assembly 208 may generate heat during operation of the microphone assembly 200 and may thus alternatively be referred to herein as heat sources in this context. For example, heat sources may comprise one or more of the audio ICs that may be associated with one or more microphones of the PCB assembly 208. Alternatively, the heat sources may comprise any suitable electronic components that may be part of the microphone assembly 200 or other suitable type of assembly (e.g. a speaker assembly). For example, the heat sources as discussed herein may comprise discrete electronic components (e.g. transistors, resistors, capacitors, etc.) or any suitable electronic component that may comprise part of or the entirety of an IC package (e.g. a chip), which may include audio ICs as well as non-audio ICs. The heat sources as discussed herein may thus include both audio electronic components as well as non-audio electronic components, based upon the particular application.

The chassis 202, the heat spreader 206, the PCB assembly 208, and the grill cover 204 may be coupled to one another in a stacked arrangement as shown in FIG. 2E. The chassis 202, the heat spreader 206, the PCB assembly 208, and the grill cover 204 may be coupled to one another to thereby form the microphone assembly 200 as shown in FIGS. 2A-2E using any suitable number and type of retaining mechanisms. For example, for purposes of brevity, a single retaining mechanism 205 is shown, although it will be understood that the microphone assembly 200 may comprise any suitable number of such retaining mechanisms, which may comprise for instance screws, rivets, bolts, etc.

However, the type of retaining mechanisms, as well as the nature of the captivation that is used for the various components of the microphone assembly 200, may differ from one another. In any event, any suitable combination of retaining mechanisms may be used to ensure that the heat spreader 206 acts as a heat path from the heat source(s) on the PCB assembly 208 to the grill cover 204. For example, to ensure that the heat spreader 206 functions as a heat path in this manner, the grill cover 204 may be pulled tight to the heat spreader 206, thereby ensuring good thermal coupling between these components. Additionally or alternatively, and as yet another example, the PCB assembly 208 may also interface with the heat spreader 206, as discussed herein, to ensure a good thermal coupling between the heat source and the heat spreader 206. Additionally or alternatively, and as yet another example, the chassis 202 may also be coupled to the heat spreader 206, as discussed herein. When the chassis comprises a thermally conductive material, this may also ensure a good thermal coupling between chassis 202 and the heat spreader 206. Thus, the chassis 202 may be affixed to any suitable component within the mechanical system (e.g. any of the components of the microphone assemblies as discussed herein.

For example, the retaining mechanisms 205 may be used to mechanically couple the chassis 202, the heat spreader 206, and the PCB assembly 208 to one another. This may be implemented, for instance, using bosses or mating couplings that may be formed within the PCB assembly 208. The grill cover 204, however, may be snap-fit to the chassis 202 via a mechanical engagement between the recessed outer lip 203 of the chassis 202. As another example, the grill cover 204 may additionally or alternatively be retained to the PCB assembly 208 via one or more retaining mechanisms (not shown), such as screws, rivets, bolts, etc. As yet another example, the chassis 202 and/or the grill cover 204 may include threaded components and/or alternatively function as a screw cap (e.g. a decorative covering to hide the screw heads). This may be implemented, for instance, by using bosses or mated couplings that may be formed within the PCB assembly 208.

The coupled arrangement between the various components of the microphone assembly 200 is shown in further detail in FIGS. 2F and 2G. Each of FIGS. 2F and 2G illustrates a cross-sectional view and is also provided with respect to the side view orientation as shown in FIG. 2A. As shown in FIGS. 2F and 2G, the heat sources 208.1, 208.2 (which may also be referred to herein as “chips”) are shown within the microphone assembly 200, which again form part of the PCB assembly 208. The heat sources 208.1, 208.2 may be disposed on the PCB assembly 208 and be associated with any audio electronic components of the microphone assembly 200, such as one or more microphones for example, which may be used for an active microphone configuration as discussed herein.

When assembled, the heat spreader 206 may be mechanically coupled to the chassis 202 and to the PCB assembly 208. As a result, the heat spreader 206 is also thermally coupled to the heat sources 208.1, 208.2 contained within the microphone assembly 200, which may include for example the audio ICs. In other words, upon assembly of the microphone assembly 200, the PCB assembly 208 may be disposed within the microphone assembly 200 such that the heat sources 208.1, 208.2 may be each thermally coupled to a respective portion of the heat spreader via the mechanical coupling between the chassis 202, the PCB assembly 208, and the heat spreader 206. The heat spreader 206 may thus be shaped such that the heat sources 208.1, 208.2 may be thermally coupled to the heat spreader 206 by way of the use of the retaining mechanisms 205, which “draw” the heat sources 208.1, 208.2 into contact with predetermined regions of the heat spreader 206 as shown in FIGS. 2F and 2G. Optionally, the heat sources 208.1, 208.2 may be further thermally coupled to the heat spreader 206 by way of any suitable thermal interface material, examples of which may include thermal paste compound, a thermal gel, grease, gap pads, etc., which may be applied for example between the heat sources 208.1, 208.2 and the predetermined regions of the heat spreader 206 that may be in contact with the heat sources 208.1, 208.2.

Upon assembly, the grill cover 204 may also be thermally coupled to the heat spreader 206 by way of tension that is provided between the various components of the microphone assembly 200. For example, the various audio electronic components may be mounted to the PCB assembly 208 and, upon mechanically coupling the chassis 202 to the heat spreader 206 and the PCB assembly 208, the heat sources 208.1, 208.2 may be thermally coupled to respective portions of the thermally-conductive heat spreader, as noted above. In this way, the PCB assembly 208 may be disposed within the microphone assembly 200 such that the heat sources 208.1, 208.2 may be thermally coupled to respective portions of the heat spreader via a coupling between the chassis 202, the PCB assembly 208, and the heat spreader 206. For instance, and as shown in FIG. 2E, the heat spreader 206 may comprise an outer circumferential perimeter, with the PCB assembly 208 being disposed within this region of the heat spreader 206.

The contacting circumference of the heat spreader 206 may thus represent a portion of the heat spreader 206 that is in contact with a corresponding portion of the grill cover 204 by way of the retention of the components of the microphone assembly 200 as discussed herein. This region of thermal contact is also illustrated in FIG. 2G via the two circles denoting “thermal contact.” Due to this contact between the heat spreader 206 and the grill cover 204, a thermal coupling may also be provided between these components. Moreover, as a result of this thermal coupling, the heat spreader 206 may be configured to provide a heat path from the heat sources 208.1, 208.2 to the grill cover 204, thereby enabling the grill cover 204 to function as a heat sink for the heat sources 208.1, 208.2.

To do so, the heat spreader 206 may be comprised of any suitable type of thermally-conductive material. The heat spreader 206 may have any suitable size and shape, as noted herein, and may be comprised of a monolithic thermally-conductive material. For instance, the heat spreader 206 may be comprise of a single block of thermally-conductive material, which may be machined via any suitable techniques such as Computer Numerical Control (CNC) machining for instance, cast, etc. Some examples of the thermally-conductive materials implemented for the heat spreader 206 may comprise aluminum, cast aluminum, zinc alloys, steel, stainless steel, etc. The grill cover 204 may be comprised of the same type of thermally-conductive material as the heat spreader 206 or a different type of material. For instance, to increase the efficiency of the heat transfer process, the heat spreader 206 may comprise a thermally-conductive material having a lower thermal conductivity than the thermally-conductive material of the grill cover 204, or vice-versa.

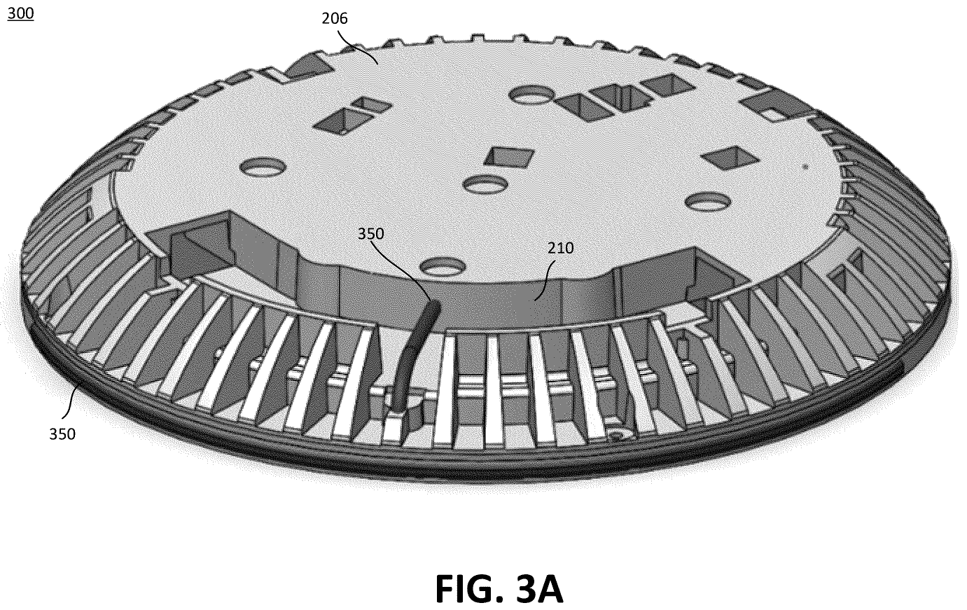

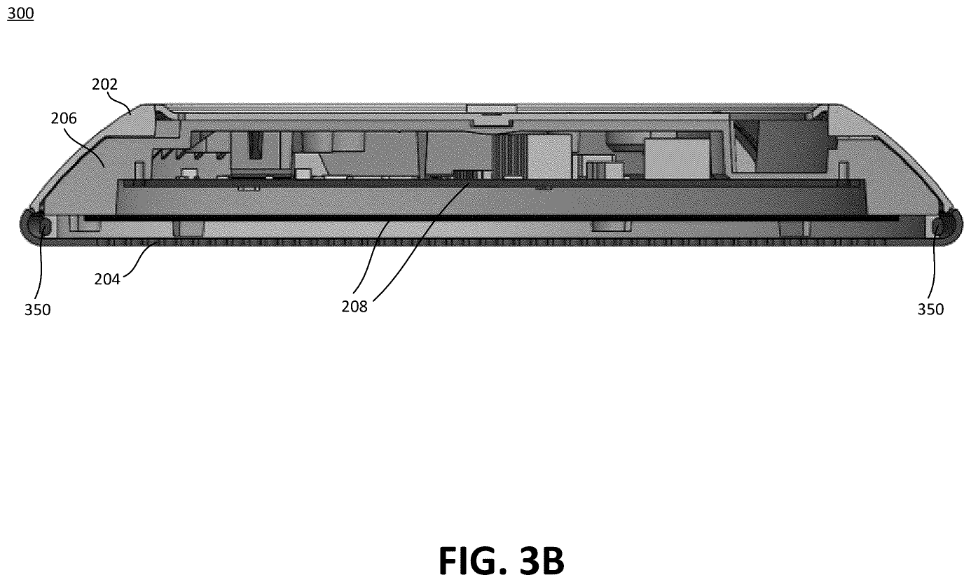

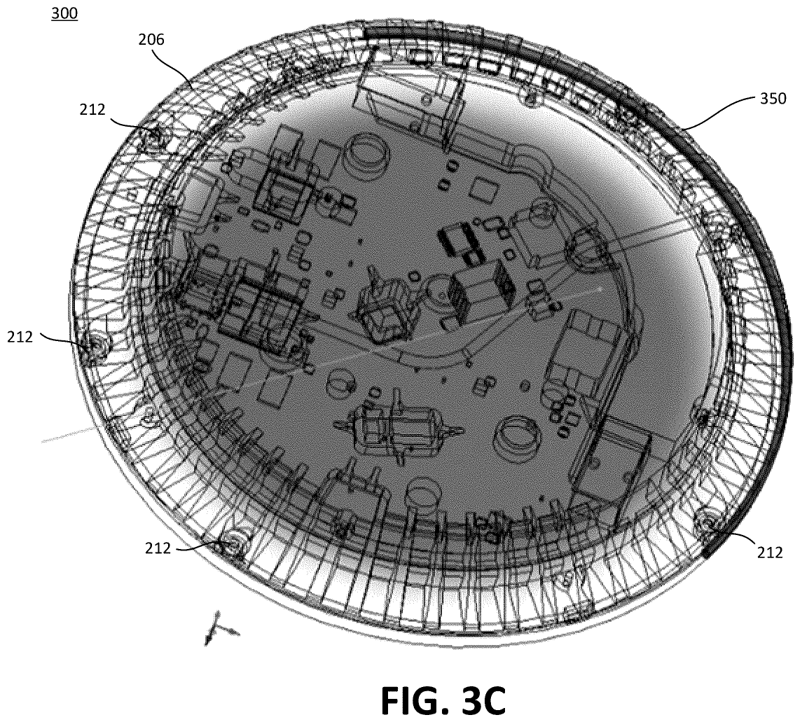

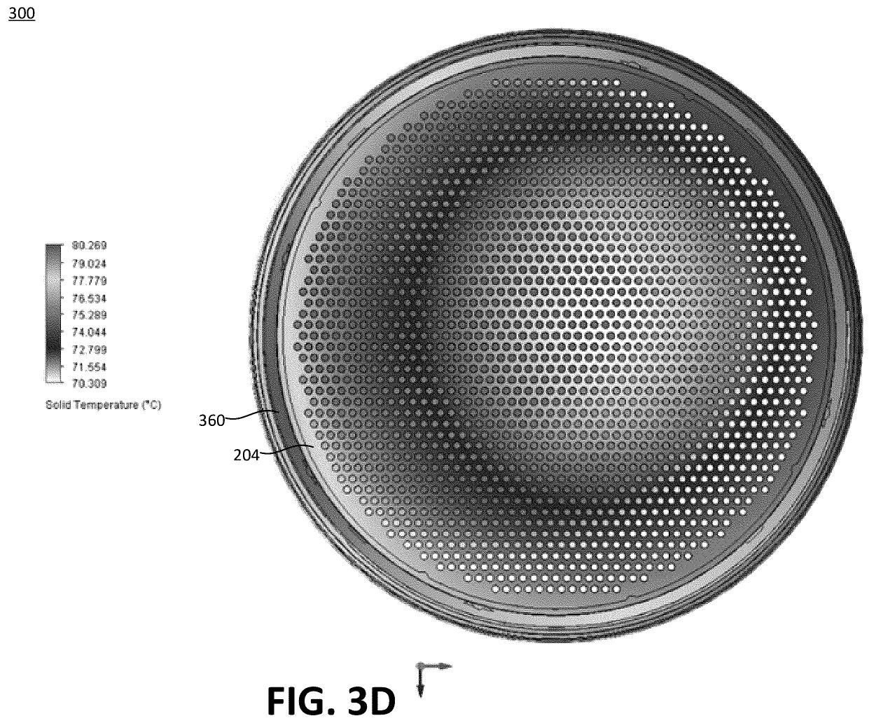

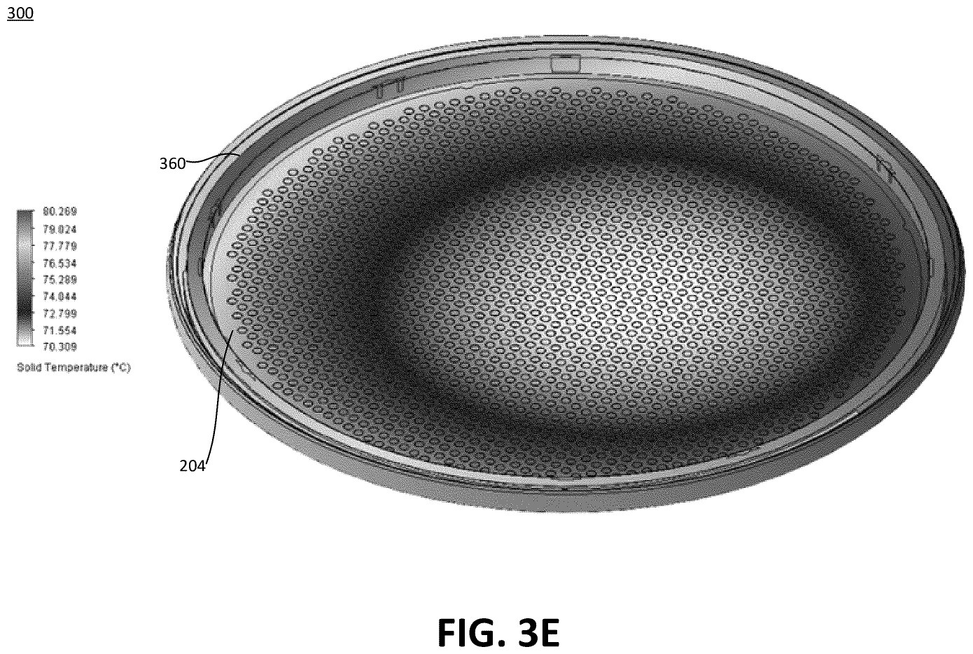

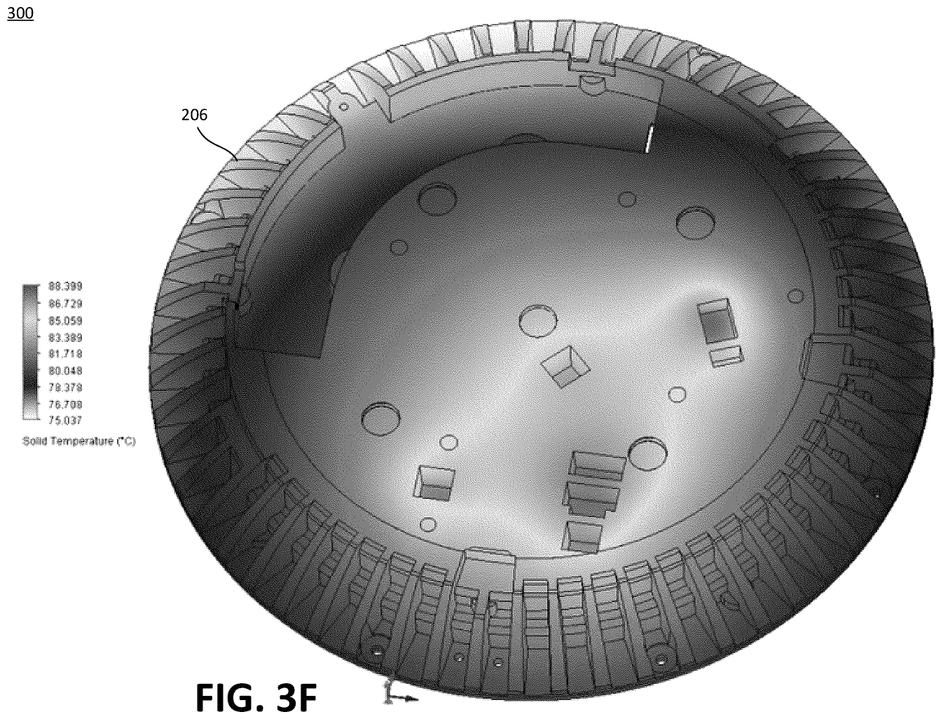

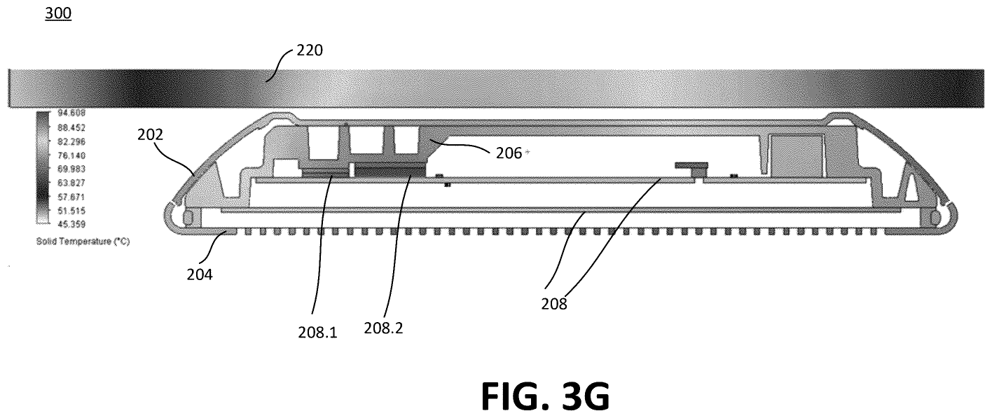

Again, the microphone assembly 200 as shown and described with reference to FIGS. 2A-2E is provided by way of example and not limitation. The various components of the microphone assembly 200, such as the chassis 202, the heat spreader 206, the PCB assembly 208, the grill cover 204, etc., may be modified in various applications. To this end, FIGS. 3A-3C illustrate example views of the microphone assembly as shown in FIGS. 2A-2G comprising a heat pipe, which may be used to implement one or more illustrative aspects described herein.

FIG. 3A illustrates a portion of a microphone assembly 300, which may be otherwise identical to the microphone assembly 200 other than the differences as further described herein. The various components of the microphone assembly 300 may operate in a similar or identical manner as their analogous counterparts of the microphone assembly 200. Thus, any of the statements made with respect to the microphone assembly 200 may also apply to the microphone assembly 300.

As shown in FIG. 3A, the heat spreader 206 includes a heat pipe 350. The heat pipe 350 may be comprised of any suitable type of materials such that the heat pipe 350 may be configured to distribute heat across one or more components of the microphone assembly 300. For example, the heat pipe 350 may be configured to distribute heat across and thus improve the uniformity of heat distribution across the heat spreader 206 and/or the grill cover 204, thereby resulting in a more uniform heat distribution. The heat pipe 350 may be comprised of any suitable materials to realize this functionality, including known heat pipe material types such as copper, aluminum, or any other suitable metals with a sufficiently high thermal conductivity, and may contain a working fluid (e.g., a phase change material such as water) and a capillary structure (e.g. a wick). Uniformity of heat distribution in this context may comprise, for example, a reduction in the difference between the minimum and maximum temperatures over an applicable surface compared to operation without the heat pipe 350. Thus, to provide an illustrative example, uniformity of heat distribution may be represented as a 1%, 5%, 10%, 15%, 20%, etc. of the difference between such minimum and maximum temperatures.

The use of the heat pipe 350 may be particularly useful, for instance, to provide better heat distribution uniformity and to avoid the presence of hot spots of regions of the microphone assembly 200 that may be prone to being touched by users. To do so, the heat pipe 350 may be mechanically and thermally coupled to the heat spreader 206 in any suitable manner, including known techniques that may be implemented to provide this arrangement. For example, the heat spreader 206 may be configured to accommodate the heat pipe 350 via a series of grooves, holes, etc., which may be formed in the heat spreader 206 and which may follow a specific path and shape. The heat pipe 350 may thus be thermally coupled to the heat spreader 206 along an entirety of this path or any portion thereof.

For example, the heat pipe 350 as shown in FIG. 3A includes one end that opens into the channel 210, and may thus be exposed to air external to the microphone assembly 200. The heat pipe 350 may then be routed through a hole in the heat spreader 206 and be disposed about a partial circumference of the heat spreader 206. This portion of the heat spreader 206 may correspond, for example, to a portion of the circumference of the heat spreader 206 that may be in contact with a corresponding portion of the grill cover 204 as discussed herein. It is noted that the heat pipe 350 may be coupled to any portion of the heat spreader 206, although it may be particularly advantageous to couple the heat pipe 350 to portions of the heat spreader 206 that are anticipated to have a higher temperature compared to other portions. For example, one or more portions of the heat pipe 350 may additionally or alternatively be coupled to (or proximate to) the predetermined regions of the heat spreader 206 as shown in FIGS. 2F and 2G, which may be in thermal contact with the heat sources 208.1, 208.2.

FIG. 3B provides a side, cross-sectional view of the microphone assembly 300, which again may be identical to the microphone assembly 200 as discussed above but includes the heat pipe 350. The microphone assembly 300 as shown in FIG. 3B shows the heat pipe 350 disposed about a circumferential section of the heat spreader 260, which may include the entire circumference or any suitable portion thereof.

FIG. 3C illustrates a wireframe and alternate view of the microphone assembly 300 as discussed above with respect to FIGS. 3A and 3B. The microphone assembly 300 as shown in FIG. 3C shows the heat pipe 350 disposed less than half the circumference of the heat spreader 260, but again may include the entire circumference or any suitable portion thereof. FIG. 3C also illustrates various through holes 212 that may be formed in the heat spreader 260, which may be used to retain the chassis 202, the heat spreader 206, and the PCB assembly 208 to one another as noted herein. The holes 212 are also shown in FIG. 2F.

For the sake of comparison of thermal performance with and without a heat pipe, FIGS. 3D-3E illustrates an example thermal maps of the microphone assembly as shown in FIGS. 2A-2G during operation without a heat pipe, which may be used to implement one or more illustrative aspects described herein. However, FIGS. 3F-3G illustrate example thermal maps of the microphone assembly as shown in FIGS. 2A-2G comprising a heat pipe, which may be used to implement one or more illustrative aspects described herein.

The thermal maps as shown in FIGS. 3D and 3E indicate a hot spot 360 associated with a region of the periphery of the grill cover 204, which is over 80 degrees Celsius. However, due to the use of the heat pipe 350, the thermal maps as shown in FIGS. 3F-3G indicate both a reduction in the temperature of the hottest point on the surface of microphone assembly 300 as well as a more uniform heat distribution. For instance, FIG. 3F may correspond to the same view of the heat spreader 260 as shown in FIG. 3A, which illustrates that the hottest region of the heat spreader 260 is near the heat sources. Additionally, FIG. 3G may correspond to the same view of the microphone assembly 200 as shown in FIGS. 2F and 2G but with the use of the heat pipe 350. Again, and as shown in FIG. 3G, the hottest region of the heat spreader 260 is near the heat sources 208.1, 208.2, with the surface of the chassis 202 and the grill cover 204 having a more uniform heat distribution as well as lowered maximum temperature regions due to the implementation of the heat pipe 350.

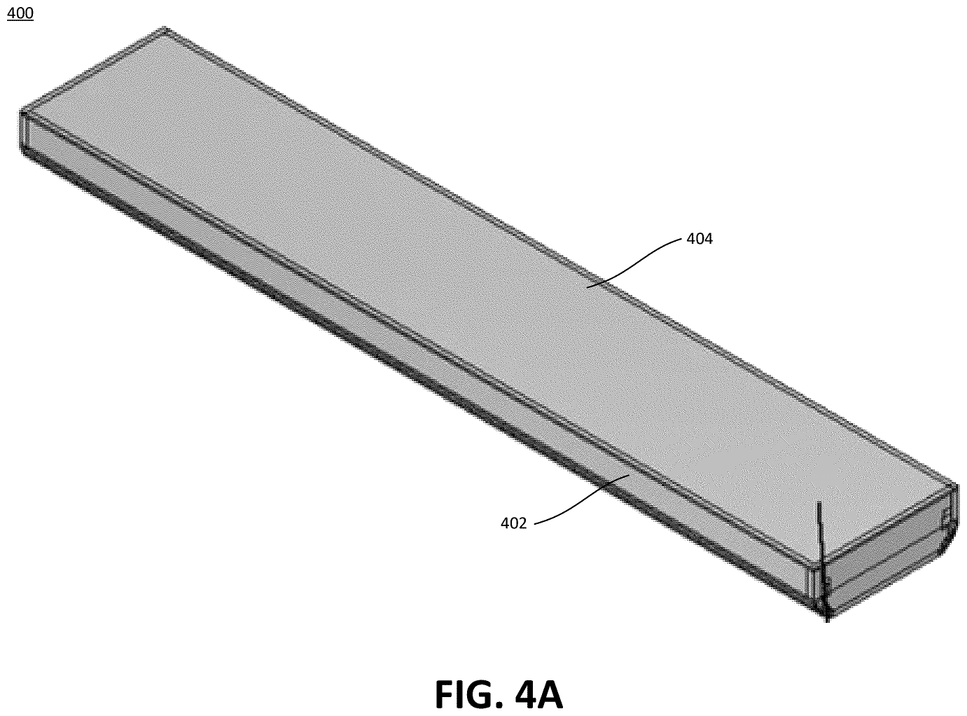

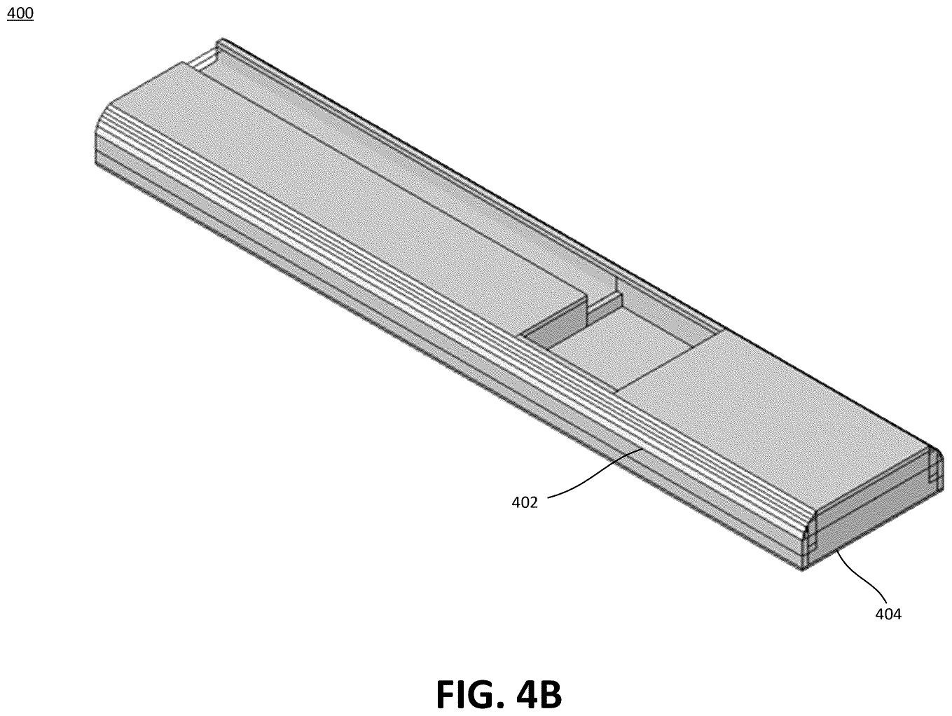

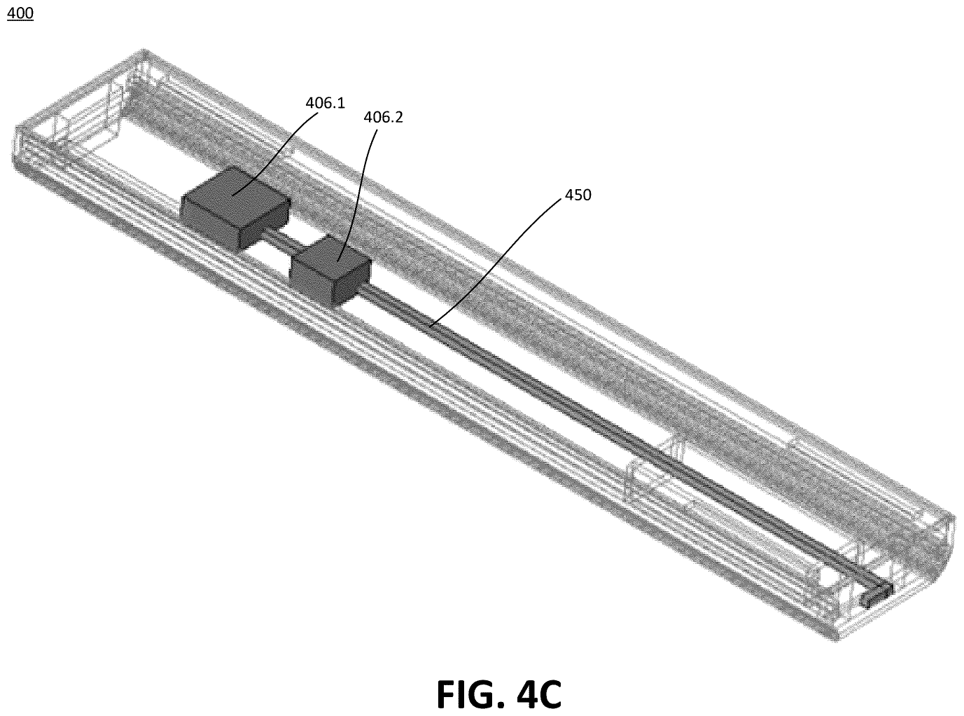

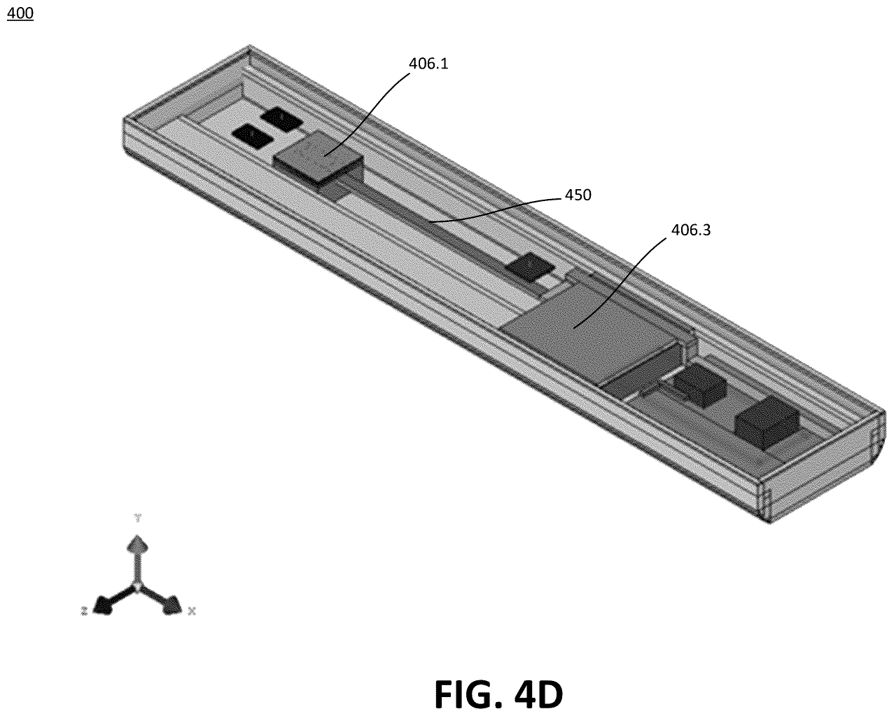

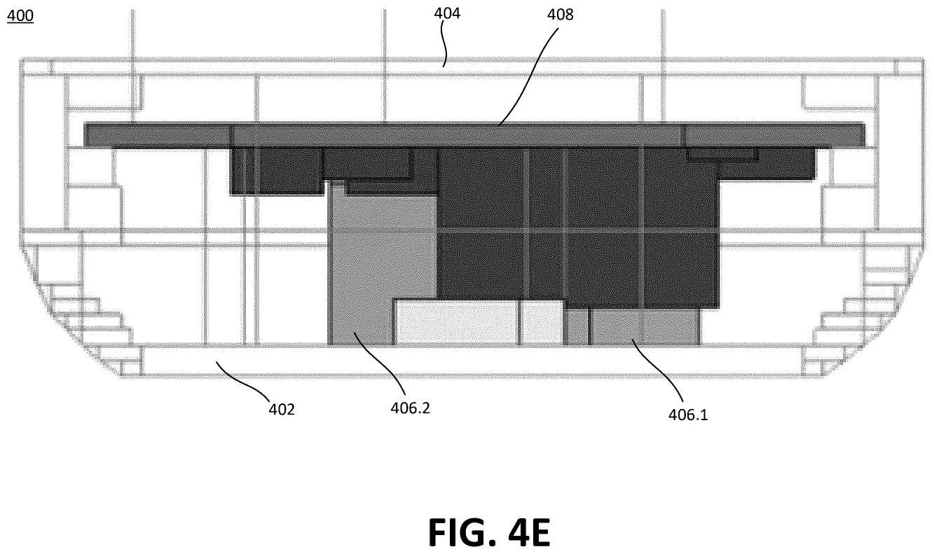

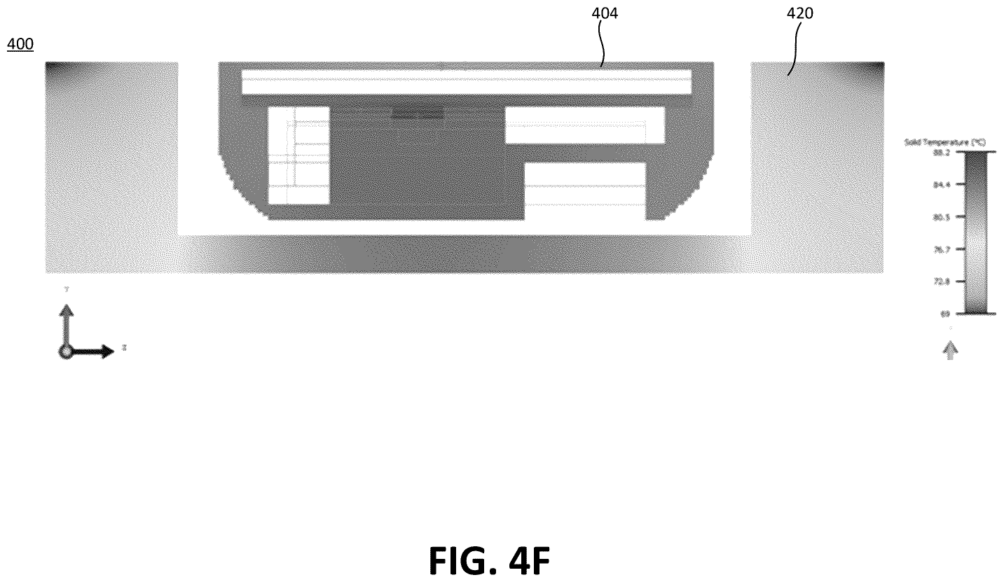

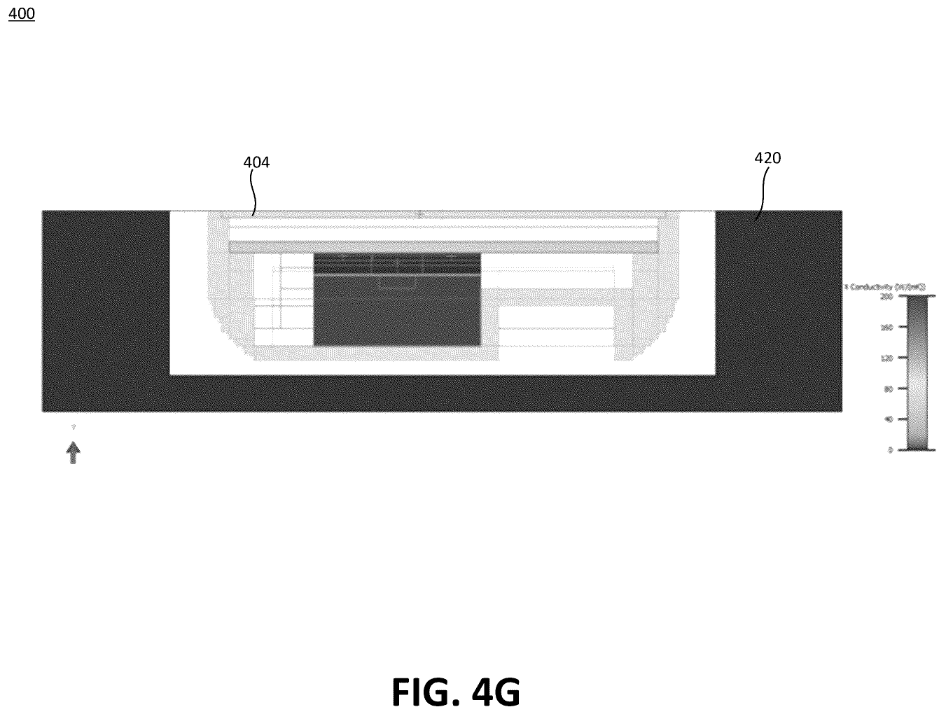

Again, the various components of the microphone assembly 200, such as the chassis 202, the heat spreader 206, the PCB assembly 208, the grill cover 204, etc., may be modified in various applications. To this end, FIGS. 4A-4E illustrate example views of an alternate microphone assembly, which may be used to implement one or more illustrative aspects described herein. Additionally, FIG. 4F illustrates an example thermal map of the microphone assembly as shown in FIGS. 4A-4E, which may be used to implement one or more illustrative aspects described herein, and FIG. 4G illustrates an example thermal conductivity map of the microphone assembly as shown in FIGS. 4A-4E, which may be used to implement one or more illustrative aspects described herein.

Similar to the microphone assemblies 200, 300, the microphone assembly 400 as shown in FIGS. 4A and 4B may also comprises a chassis 402 and a grill cover 404. FIG. 4A may represent a view from the top of the microphone assembly 400, whereas FIG. 4B may represent a bottom view. FIGS. 4C-4D may correspond to the view as shown in FIG. 4A, with the grill cover 404 removed to show additional detail of the inside of the microphone assembly 400. FIGS. 4E-4G may correspond to a cross-sectional side view of the microphone assembly 400 as shown in FIGS. 4A-4D. As shown in FIG. 4E, the microphone assembly 400 may also comprise a PCB assembly 408, which includes various audio electronic components such as microphones, audio ICs, etc. The microphone assembly 400 may also include a heat spreader 406, with only the predetermined regions 406.1, 406.2 of the heat spreader 406 being shown in FIGS. 4C and 4E, with an additional example predetermined region 406.3 of the heat spreader 406 being shown in FIG. 4D. Again, each of these predetermined regions 406.1-406.3 of the heat spreader 406 may be in thermal contact with a corresponding heat source of the PCB assembly 408, as discussed above with respect to the microphone assemblies 200, 300.

The various components of the microphone assembly 400 may operate in a similar or identical manner as their analogous counterparts of the microphone assemblies 200, 300, and thus any of the statements made with respect to the microphone assemblies 200, 300 may also apply to the microphone assembly 400, with the differences between the microphone assemblies, 200, 300, 400 being discussed herein. For instance, the microphone assembly 400 may be larger in size, have a different shape, and be wall and/or table mounted versus the configuration of the microphone assemblies 200, 300, which may be ceiling mounted for instance. Nonetheless, the heat spreader 406, like the heat spreader 206, may be configured to provide a heat path between the various heat sources of the PCB assembly 408 and the grill cover 404, which likewise functions as a heat sink.

FIG. 4C illustrates a wireframe view of the microphone assembly 400, which includes a heat pipe 450. FIG. 4D illustrates a solid view of the microphone assembly 400 from the same viewpoint as the microphone assembly 400 as shown in FIG. 4C. As shown in FIGS. 4C and 4D, the microphone assembly 400 may include a heat pipe 450. The heat pipe 450 may be disposed linearly along a longitudinal direction of the microphone assembly 400 and be routed through the predetermined regions 406.1, 406.2, 406.3, etc., of the heat spreader 406, which again may be in thermal contact with the audio IC chips or other heat sources of the PCB assembly 408. Of course, this is also by way of example and not limitation, and the heat pipe 450 may have any suitable size, shape, routing, etc., to improve the uniformity of heat distribution across the heat spreader 406 and/or the grill cover 404.

FIGS. 4F and 4G also illustrate the thermal performance of the microphone assembly 400 as part of an installation that incorporates a low thermal conductivity component 420. This low thermal conductivity component 420 may include, for example, a table, a wall, a ceiling, etc. Thus, upon installation the grill cover 404 may be mounted flush with or slightly recessed beneath a surface of the low thermal conductivity component 420. FIG. 4F illustrates that the microphone assembly 400, upon being installed in this manner, may exhibit a maximum surface temperature of about 88 degrees Celsius, with the grill cover being about 80 degrees Celsius. The low thermal conductivity component 420 is much cooler than this temperature, particularly in the region proximate to the grill cover 404.

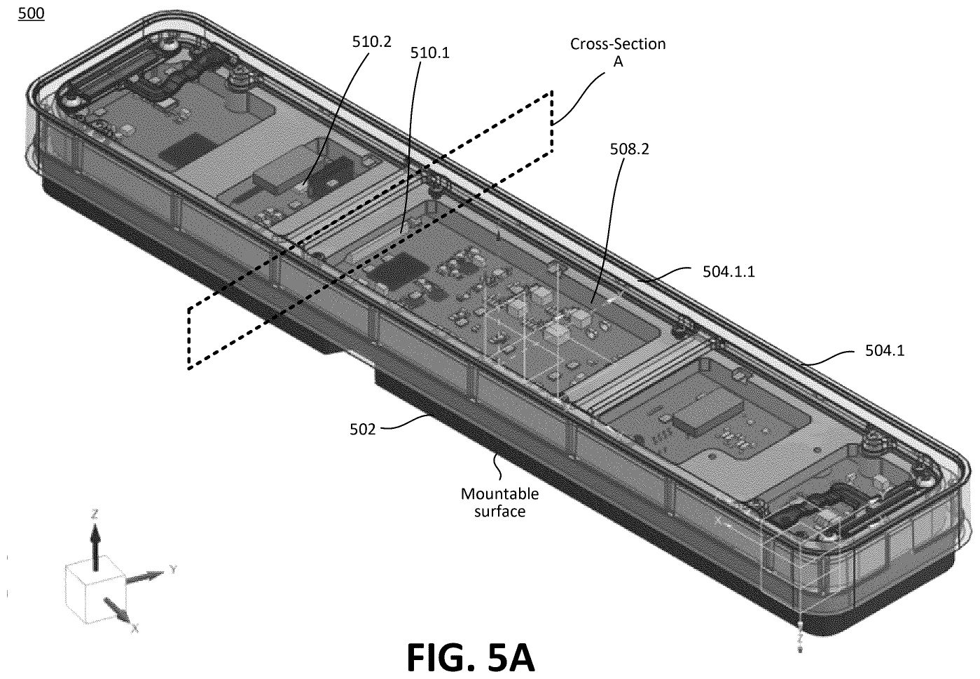

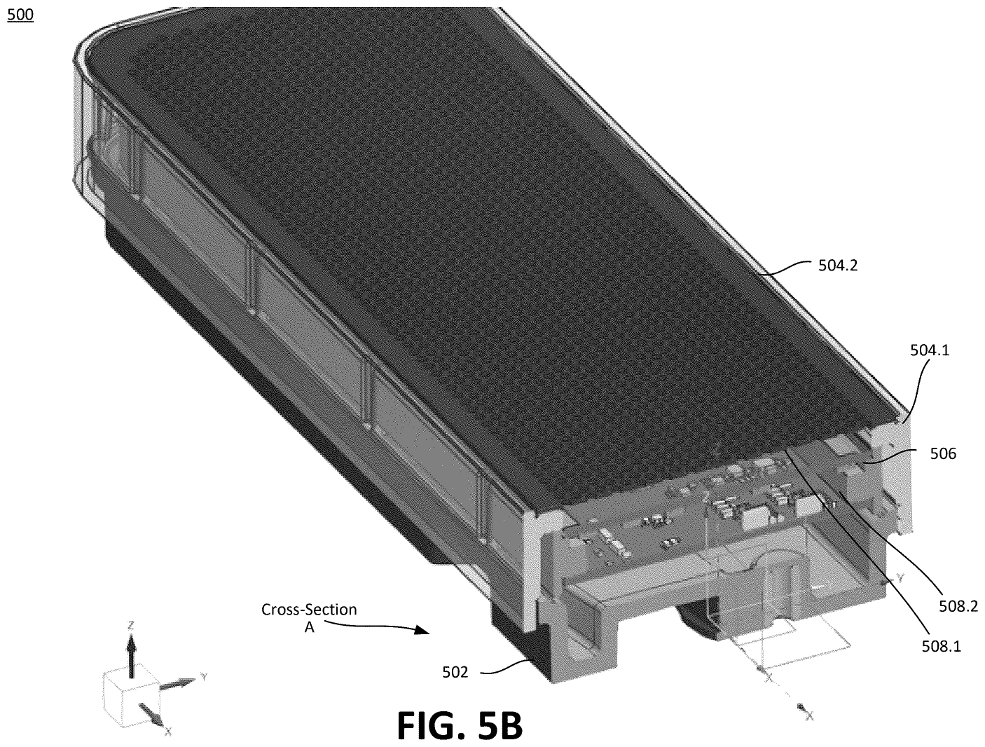

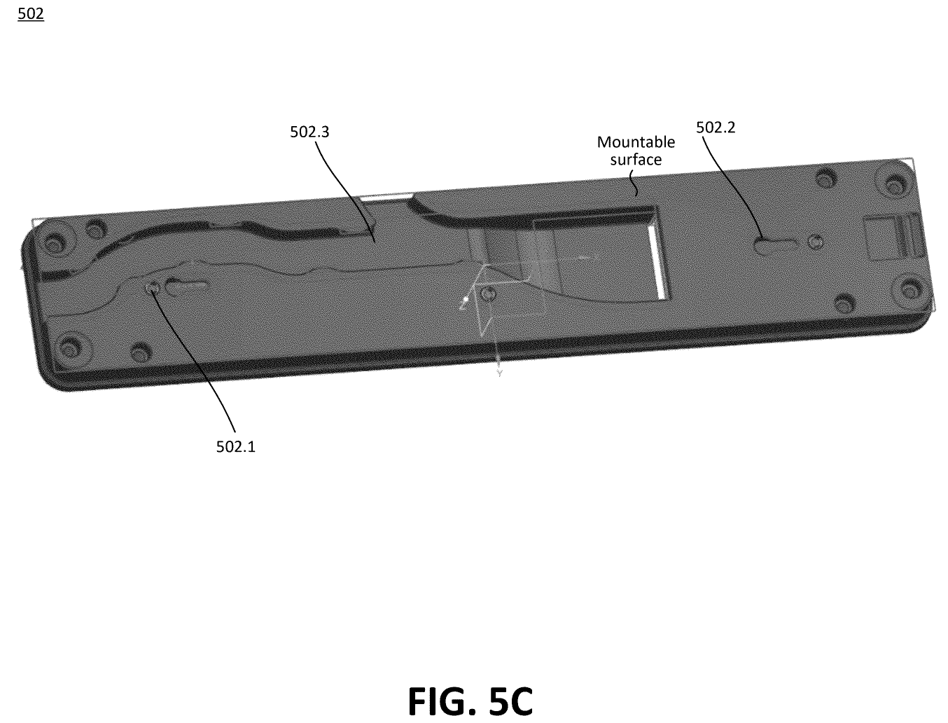

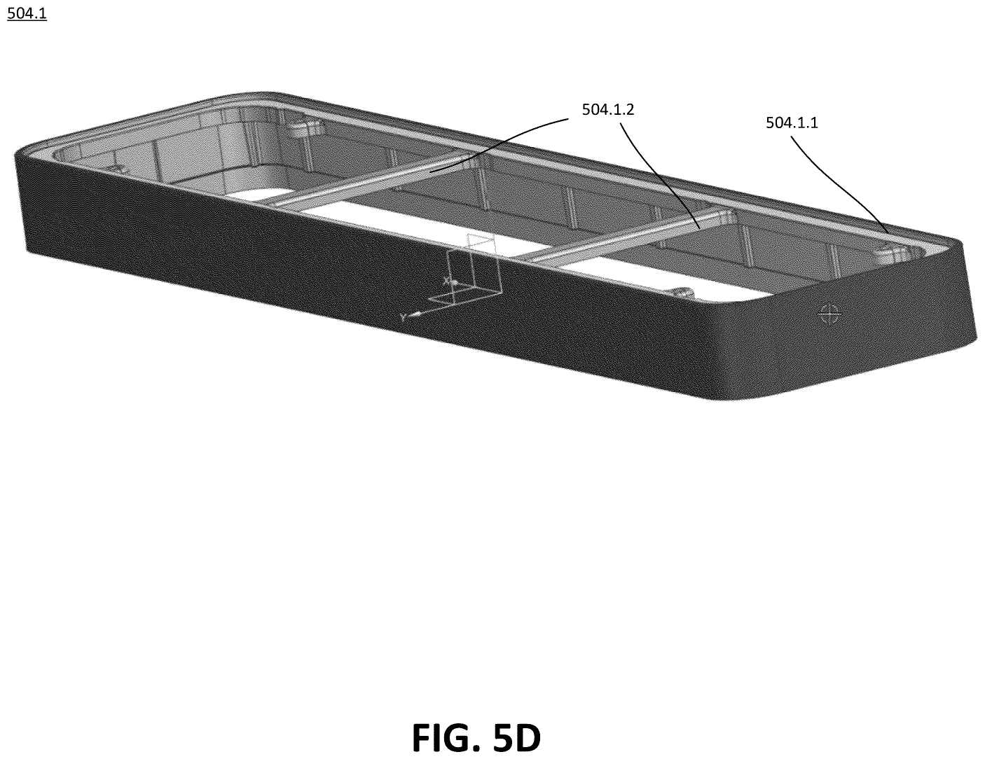

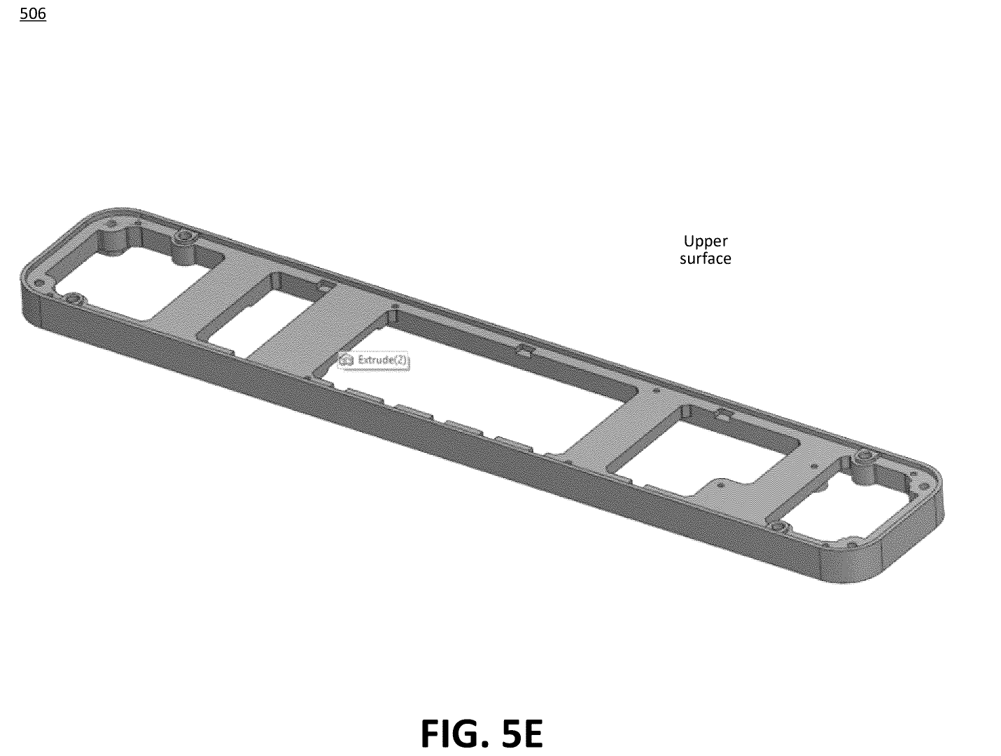

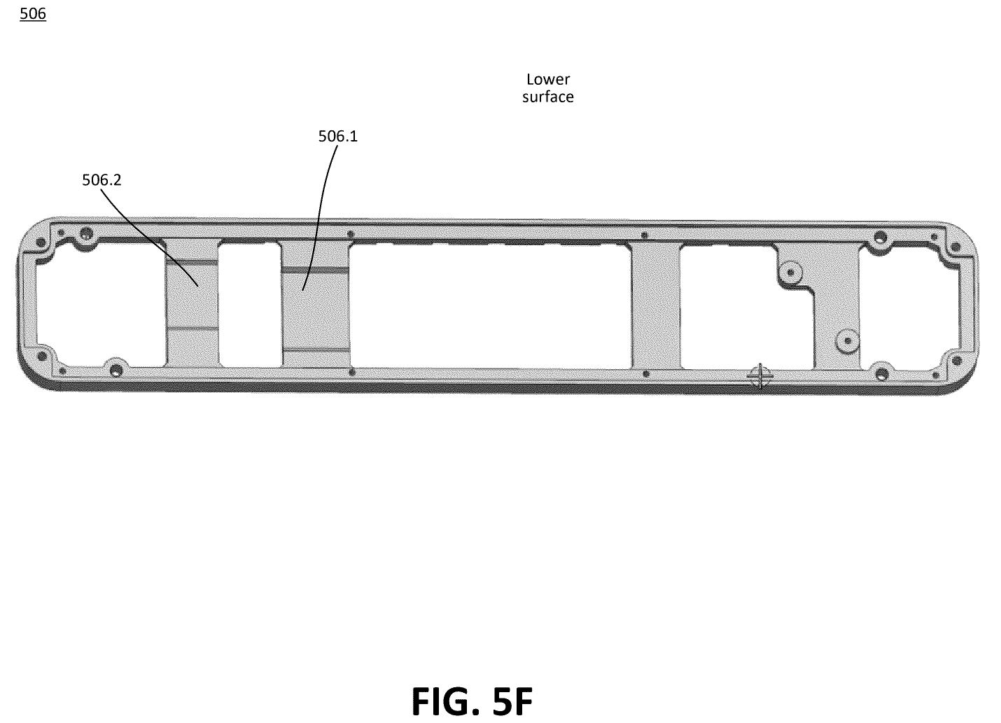

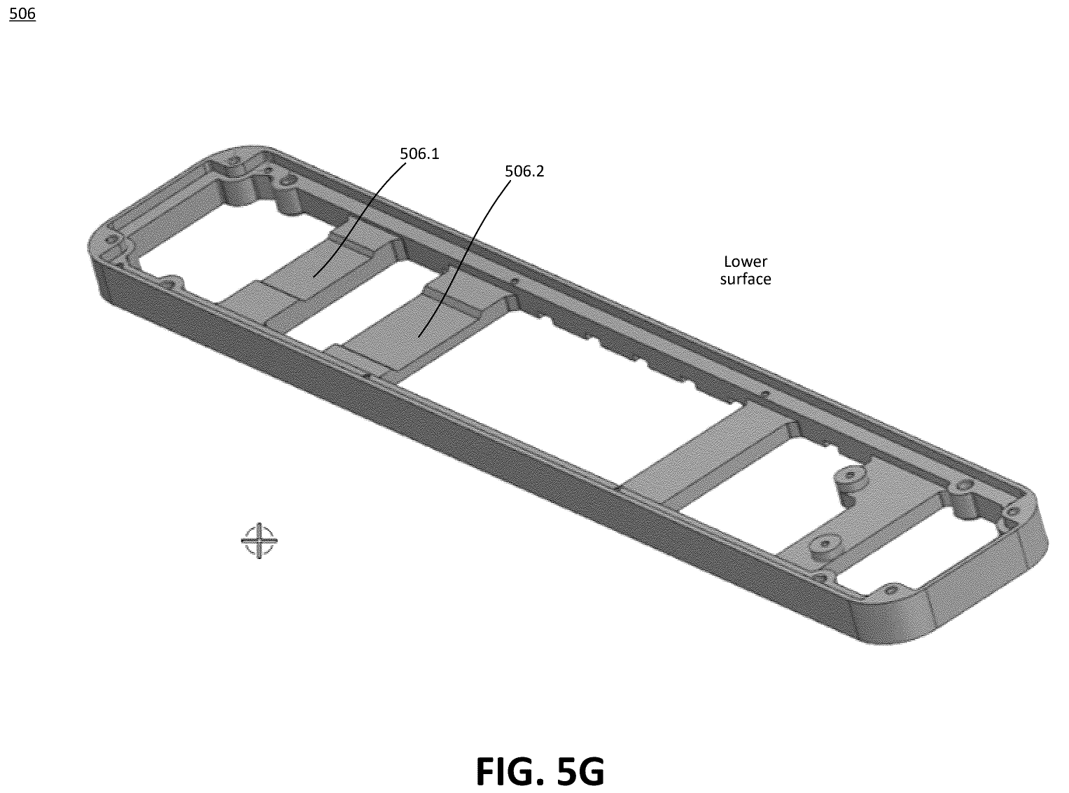

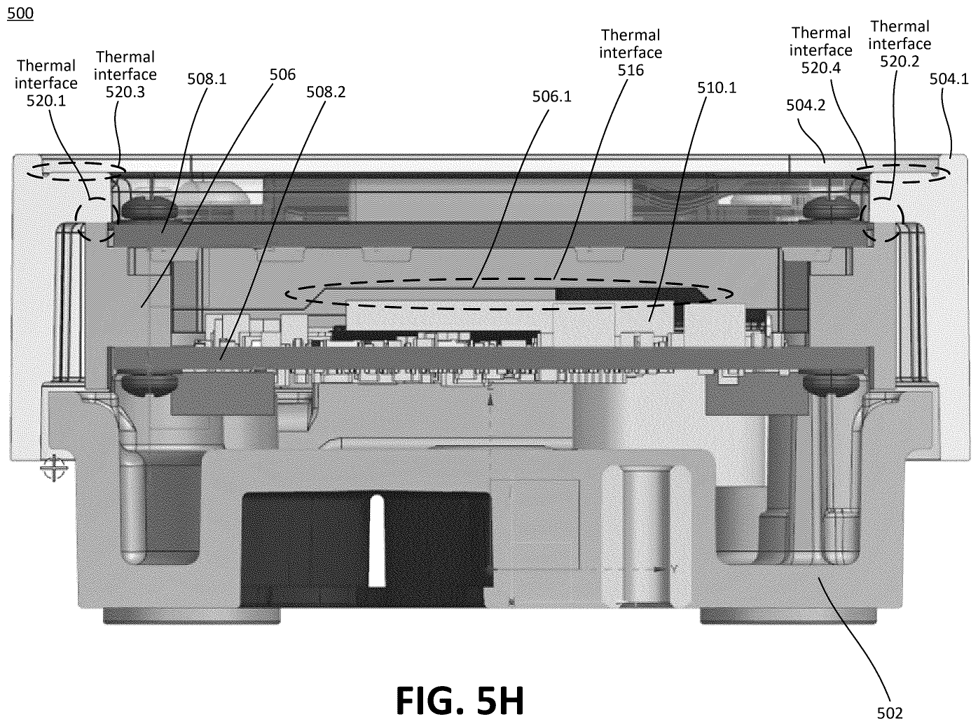

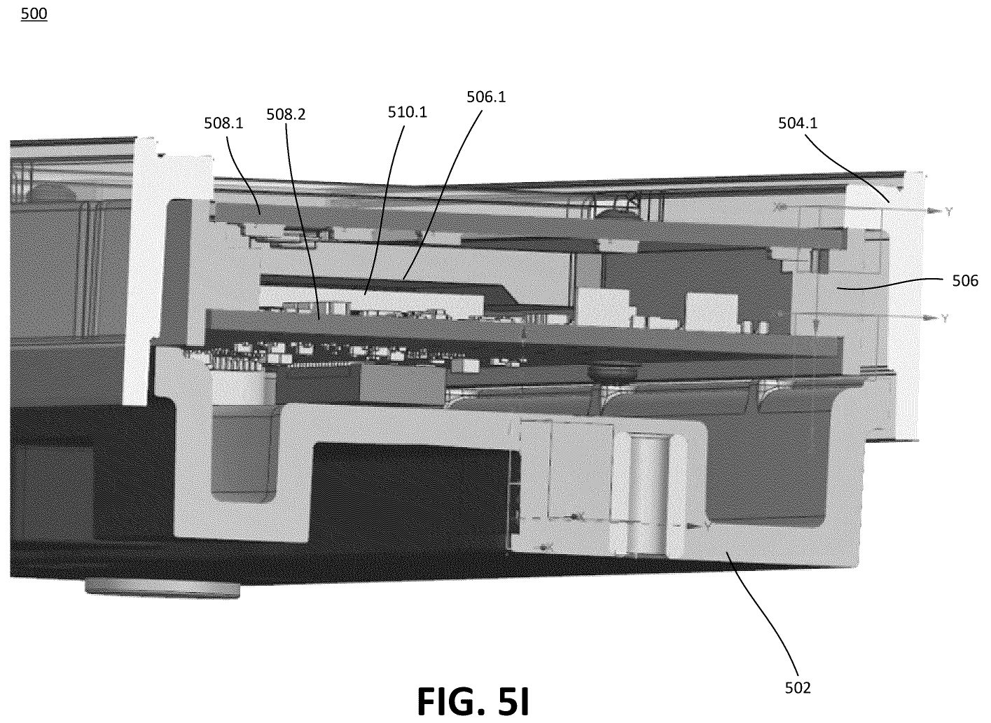

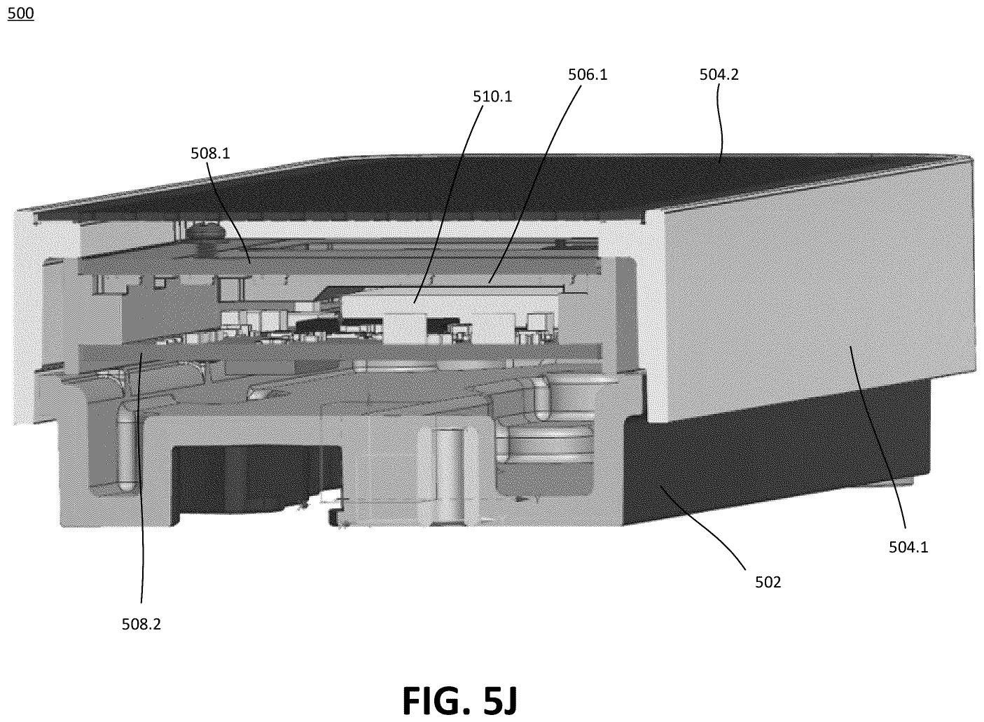

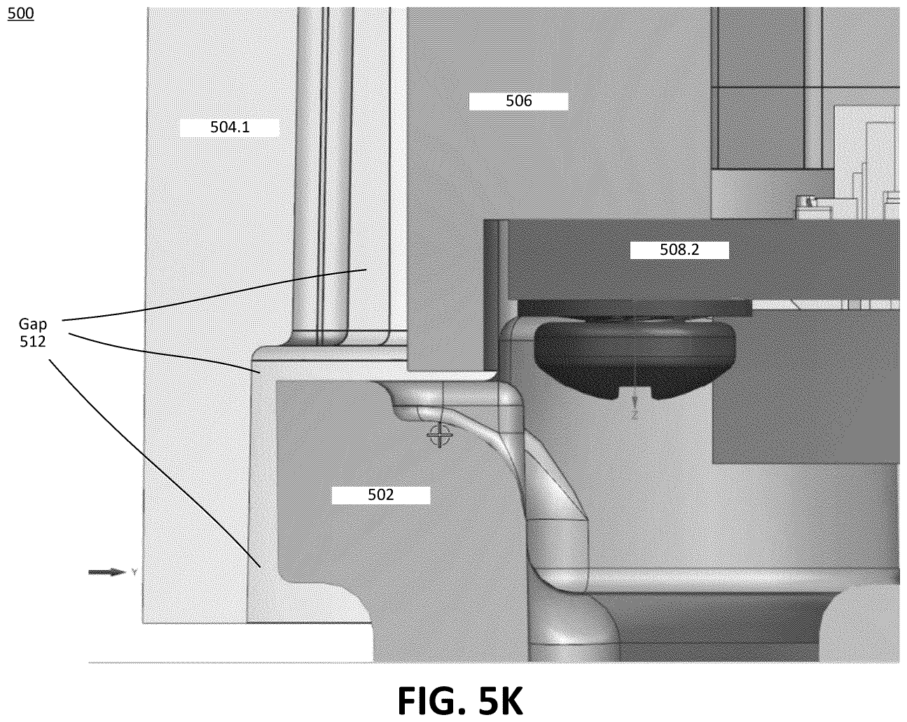

FIGS. 5A-5K illustrate example views of a further microphone assembly that may be used to implement one or more illustrative aspects described herein. Similar to the microphone assemblies 200, 300, 400, the microphone assembly 500 as shown in FIGS. 5A-5K may also comprise one or more chassis components and a grill cover. The various components of the microphone assembly 500 may operate in a similar or identical manner as their analogous counterparts of the microphone assemblies 200, 300, 400, and thus any of the statements made with respect to the microphone assemblies 200, 300, 400 may also apply to the microphone assembly 500, with the differences between the microphone assemblies, 200, 300, 400, 500 being further discussed herein.

For instance, the microphone assembly 500 may be implemented in a similar manner as the microphone assembly 400, and thus be larger in size, have a different shape, and be wall and/or table mounted versus the configuration of the microphone assemblies 200, 300, which may be ceiling mounted for instance. That is, and as further discussed below, the microphone assembly 500 may include a grill cover assembly 504 including a thermally-conductive upper chassis 504.1 and a thermally-conductive grill cover 504.2. The grill cover assembly 504 may be a monolithic component or, alternatively and as discussed further herein, the upper chassis 504.1 and grill cover 504.2 may comprise separate components that are thermally and mechanically coupled to one another. The microphone assembly 500 may also include a heat spreader 506 that, like the heat spreaders 206, 406, may also be configured to provide a heat path between the various heat sources of a PCB assembly and the grill cover 504.2, which may be for instance by way of the thermally-conductive upper chassis 504.1 to which the heat spreader 506 is also thermally coupled. Thus, the grill cover 504.2 of the microphone assembly 500 may also function as a heat sink, with additional details regarding the mechanical and thermal configuration of the microphone assembly 500 being provided below.

FIG. 5A may represent a 3D view of the microphone assembly 500. As shown in FIG. 5A, the microphone assembly 500 may comprise a lower chassis 502 and an upper chassis 504.1. Again, the upper chassis 504.1 may form part of grill cover assembly 504, as further discussed herein. The microphone assembly 500 may further include a PCB assembly 508, which may comprise any suitable number of PCBs, each occupying a separate layer of the PCB assembly 508, with two being shown in the Figures by way of example and not limitation. For instance, the PCB assembly 508 may include an upper PCB 508.1 and a lower PCB 508.2, each including any suitable number of audio electronic components and/or other components depending upon the particular implementation and application. For example, the upper and/or lower PCB 508.1, 508.2 may include one or more microphones, one or more integrated circuits (ICs) such as audio ICs and/or power management ICs for example, other suitable types of circuits and/or circuit components, connectors, etc., as discussed above for instance with respect to the PCB assemblies 208, 408.

Again, any components of the PCB assembly 508 may generate heat during operation of the microphone assembly 500 and may thus alternatively be referred to herein as heat sources 510 in this context. For example, the heat sources 510 may comprise one or more of audio ICs that may be associated with one or more microphones of the PCB assembly 508. Alternatively, the heat sources 510 may comprise any suitable electronic components that may be part of the microphone assembly 500 or other suitable type of assembly (e.g. a speaker assembly). For example, the heat sources 510 as discussed herein may comprise discrete electronic components (e.g. transistors, resistors, capacitors, etc.) or any suitable electronic component that may comprise part of or the entirety of an IC package (e.g. a chip), which may include audio ICs as well as non-audio ICs. The heat sources 510 as discussed herein may thus include both audio electronic components as well as non-audio electronic components, based upon the particular application.

The microphone assembly 500 as shown in FIGS. 5A-5K may thus include any suitable number of such heat sources 510, with two heat sources 510.1, 510.2 being implemented as discussed herein by way of example and not limitation. These heat sources are shown for instance in FIG. 5A as heat sources 510.1, 510.2, which again may comprise an audio IC or other suitable electronic component for which thermal management is implemented during operation of the microphone assembly 500. The heat sources 510.1, 510.2 are thus shown in the Figures as being part of the PCB 508.2, although this is likewise by way of example and not limitation. The thermal and mechanical interoperation between the heat sources 510.1, 510.2 and the other components of the microphone assembly 500 are further discussed below.

The lower chassis 502 may be comprised of any suitable materials, which may include thermally conductive materials such as a metal (e.g. aluminum, cast aluminum, zinc alloys, steel, stainless steel, etc.) or non-thermally conductive (e.g. polymers). The lower chassis 502 is shown in further detail in FIG. 5C from a bottom-facing perspective, i.e. the bottom of the microphone assembly 500 opposite to the grill cover 504.2. The surface of the lower chassis 502 as shown in FIG. 5C may comprise a mountable surface of the microphone assembly 500 that may include any suitable number of cutouts and/or mounting components for this purpose, such as for instance the threaded bosses 502.1, slotted cutouts 502.2, etc. The lower chassis 502 may also be formed of any suitable size and/or shape and include other suitable recesses, cutouts, etc., based upon the particular application. For instance, the lower chassis 502 as shown in FIG. 5C may include a channel 502.3 that may be configured to accept any suitable type of cable, wiring, etc. for cable routing and/or management, which may allow Ethernet cables or other suitable cables to be coupled to the components of the microphone assembly 500 via a suitable connector.

The upper chassis 504.1 may be comprised of any suitable thermally conductive materials, such as a metal (e.g. aluminum, cast aluminum, zinc alloys, steel, stainless steel, etc.). The upper chassis 504.1 is shown in further detail in FIG. 5D, which includes a cutback 504.1.1 that may be configured to receive the grill cover 504.2. The upper chassis 504.1 may include any suitable number of ribs 504.1.2, such as the two as shown in FIG. 5D, which may provide support and structural integrity for the microphone assembly 500.

FIG. 5B may represent another 3D view of the microphone assembly 500, which shows a cross-sectional view at the cross-section A from FIG. 5A in further detail. As shown in FIG. 5B, the microphone assembly 500 may also include the grill cover 504.2, and may have openings and/or perforations to allow for sound to pass into the assembly and to be received by the various microphones. The grill cover 504.2 may be considered the upper portion or top of the microphone assembly 500, and may be coupled to the upper chassis 504.1 of the microphone assembly 500 in any suitable manner. For example, the grill cover 504.2 may be thermally and/or mechanically coupled to the upper chassis 504.1 via a thermal interface material or a suitable adhesive such as thermal transfer tape, other suitable thermally-conductive adhesives and/or couplings, mechanical fasteners such as rivets, screws, welds, etc. Thus, this mechanical and thermal coupling between the upper chassis 504.1 and the grill cover 504.2 may, for example, be provided by disposing the grill cover 504.2 within the cutback 504.1.1 of the upper chassis 504.1, as shown in FIG. 5A, and using any suitable thermal and mechanical conductive coupling such that the grill cover 504.2 and the upper chassis 504.1 are both thermally and mechanically coupled to one another and provide a flush top surface of the microphone assembly 500.

Thus, it is noted that the upper chassis 504.1 and the grill cover 504.2, which again together form the grill cover assembly 504, may be separate components, as shown in the Figures, and such embodiments may be particularly useful for ease of manufacturing and assembly. Alternatively, the grill cover assembly 504 may be implemented as a single monolithic component (e.g. a single cast or machined metal component). In any event, the upper chassis 504.1 and the grill cover 504.2 may function as a single thermally conductive component for purposes of enabling a heat path from the heat sources 510 of the microphone assembly 500, as further discussed herein. Thus, when implemented as separate components, the upper chassis 504.1 and the grill cover 504.2 may be implemented as the same type of material having the same thermal conductivity or, alternatively, as different types of materials having different thermal conductivities. For instance, it may be particularly advantageous for the upper chassis 504.1 to have a higher thermal conductivity than the grill cover 504.2 to enable a heat path from the heat spreader 506 to the grill cover 504.2, which again may function as a heat sink. Furthermore, it is noted that using a casting for the grill cover assembly 504 or, alternatively, for the upper chassis 504.1 and/or the grill cover 504.2, may be particularly advantageous, as casting is in general an efficient manufacturing process. Furthermore, the use of a casted components may ensure that the thermal impedance of the grill cover assembly 504, the upper chassis 504.1, and/or the grill cover 504.2, as the case may be, enables a suitable heat path from the heat sources 510 by providing such components with a wall thickness substantial enough to be (thermally) equivalent to a component having a higher thermal conductivity.

The microphone assembly 500 may include a heat spreader 506, which is shown in further detail in FIGS. 5E-5G. The heat spreader 506 may be comprised of any suitable thermally conductive materials, such as a metal (e.g. aluminum, cast aluminum, zinc alloys, steel, stainless steel, etc.). Thus, in various embodiments, the upper chassis 504.1, the grill cover 504.2, the heat spreader 506, and the lower chassis 502 may each be comprised of the same materials having the same thermal conductivity as one another, or as different materials having different thermal conductivities as one another. Alternatively, two or more of the upper chassis 504.1, the grill cover 504.2, the heat spreader 506, and the lower chassis 502 may be comprised of the same materials having the same thermal conductivity as one another, whereas other ones may have different thermal conductivities.

FIG. 5E illustrates the lower surface of the heat spreader 506, e.g. that which is oriented towards the bottom of the microphone assembly 500. FIGS. 5F-5G illustrate the upper surface of the heat spreader 506, e.g. that which is oriented towards the top of the microphone assembly 500. As shown in FIGS. 5F and 5G, the lower surface of the heat spreader 506 includes two bosses 506.1, 506.2, which may correspond to predetermined regions of the heat spreader 506 that may be in thermal contact with a corresponding heat source 510.1, 510.2 of the PCB assembly 508.2, as discussed above with respect to the microphone assemblies 200, 300, 400. In other words, and as discussed above for the heat spreaders 206, 406, the heat spreader 506 may also be shaped such that the heat sources 510.1, 510.2 may be thermally coupled to the respective bosses 506.1, 506.2 of the heat spreader 506 upon the microphone assembly 500 being fully assembled, as the heat sources 510.1, 510.2 are “drawn” into contact with the respective bosses 506.1, 506.2 of the heat spreader 506. Thus, the bosses 506.1, 506.2 may correspond to the portions of the heat spreader 506.1, 506.2 that are in thermal contact with the corresponding heat sources 510.1, 510.2 of the microphone assembly 500 when assembled. Thus, although two bosses 506.1, 506.2 are shown in the Figures, this is by way of example and not limitation, and the heat spreader 506 may include any suitable number of such bosses, which may be a function of the number of heat sources 510.

Turning now to FIGS. 5H-5J, different orientations of the cross-section of the microphone assembly 500 are shown, which illustrate the heat spreader 506 being disposed between the lower chassis 502 and the upper chassis 504.1 and the grill cover 504.2. The PCBs 508.1, 508.2 are shown as being coupled to the heat spreader 506 via screws, although any suitable mechanical couplings may be implemented. As shown for example in FIGS. 5H-5J, the PCB 508.2 may be disposed adjacent to the lower surface of the heat spreader 506, whereas the PCB 508.1 may be disposed adjacent to the upper surface of the heat spreader 506. In this arrangement, the PCB 508.2 is also shown as including the heat source 510.1, which is also shown as being thermally coupled to the boss 506.1 of the heat spreader 506 via a thermal interface 516. This thermal coupling may be implemented in any suitable manner. For instance, the heat sources 510.1, 510.2 may be thermally coupled to the respective bosses 506.1, 506.2 of the heat spreader 506 by way of any suitable thermal interface material, examples of which may include thermal paste compound, a thermal gel, grease, gap pads, etc., which may be applied for example between the heat sources 510.1, 510.2 and the bosses 506.1, 506.2 of the heat spreader 506 to form the thermal interface 516 (between the heat source 510.2 and the bosses 506.1), as shown in FIG. 5H.

And as shown in FIGS. 5H-5J, in addition to being thermally coupled to the heat sources 510 that may be implemented as part of the PCB 510.2, the heat spreader 506 may additionally be thermally coupled to the grill cover assembly 504. For instance, the heat spreader 506 may be thermally coupled to the upper chassis 504.1 via one or more thermal interfaces 520.1, 520.2, as shown in FIG. 5H. Additionally, the upper chassis 504.1 is thermally coupled to the grill cover assembly 504 via one or more thermal interfaces 520.3, 520.4. These thermal interfaces may include the use of any suitable thermal interface material such as e.g. thermal transfer tape, mechanical couplings, thermal paste compound, thermal gel, grease, gap pads, combinations of these, etc. In this way, the heat spreader 506 is configured to provide a heat path from each heat source 510 to the grill cover assembly 504 to thereby enable the thermally-conductive grill cover 504.2 to function as a heat sink for the heat source 510.

To do so, the heat spreader 506 again may be thermally coupled to the upper chassis 504.1, which is in turn thermally coupled to the grill cover 504.2. Thus, a heat path between the heat sources 510 of the microphone assembly 500 and the grill cover 504.2 is formed by way of the heat sources 510 being thermally coupled to the heat spreader 506. The heat spreader 506, in turn, forms a heat path represented by way of the thermal coupling with the upper chassis 504.1, as well as the further thermal coupling between the upper chassis 504.1 and the grill cover 504.2.

It is noted that it may be preferable for structural integrity and the overall appearance of quality for the lower chassis 502 to be comprised of a thermally conductive material, such as metal (e.g. aluminum, cast aluminum, zinc alloys, steel, stainless steel, etc.). For instance, depending upon the particular application, the microphone assembly 500 may be installed in different environments, which may expose the lower chassis 502, being the mountable surface of the microphone assembly 500, to harsh environmental conditions. For example, the microphone assembly 500 may be installed in a ceiling that exposes the lower chassis 502 to hot, stagnant dead air space above it. Additionally, the microphone assembly 500 may be installed such that the lower chassis 502 may extend into a plenum space within a building, which may be used for air circulation. Thus, in such scenarios, this may cause the lower chassis 502 to be exposed to hot circulated air. As a result, it may be advantageous to channel heat to the grill cover 504.2, which may be exposed to a cooler space, e.g. air below the ceiling or outside the plenum space.

Thus, embodiments include the lower chassis 502 and the grill cover assembly 504 being thermally isolated from one another to facilitate the grill cover 504.2 functioning as a heat sink, and to thereby channel heat towards a cooler space as noted above. This advantageously increases the thermal efficiency of the grill cover 504.2 functioning as a heat sink for the heat sources 510 while preventing the lower chassis 502 from conducting heat into other components of the microphone assembly 500 or other undesirable areas during operation. Thus, and as shown in FIG. 5K, embodiments include the upper chassis 504.1 and the heat spreader 506 each being thermally isolated from the lower chassis 502 via a gap 512. This gap 512 may be comprised of any suitable thermally insulating materials. For instance, the gap 512 may simply be an unfilled region (e.g. air) or, alternatively, the gap 512 may be filled with any suitable thermal insulator such as pastes, silicone, fiberglass, polystyrene, polyurethane, mineral wool, etc.

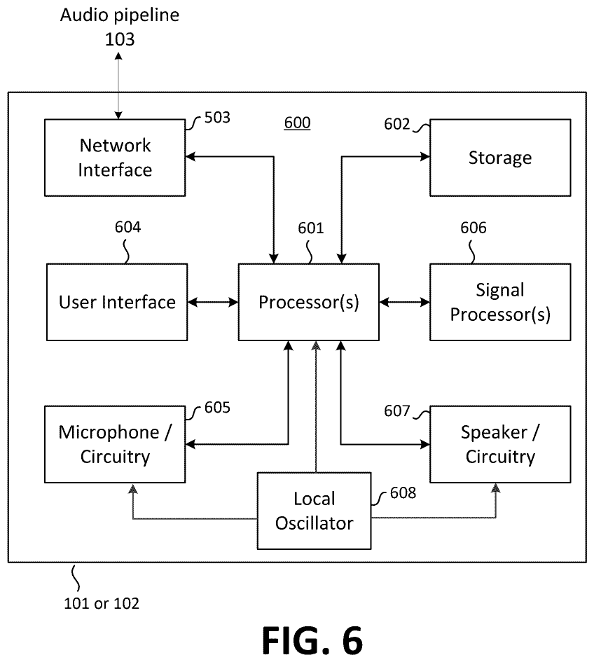

FIG. 6 is a block diagram showing example details of the various components that may be part of a microphone assembly in accordance with one or more illustrative aspects described herein. The block diagram as shown in FIG. 6 may, for example, represent details of an audio device 600 that may be part of an audio system, such as the audio system 100 of FIG. 1. For example, the audio device 600 may be identified with the audio device 101 or the audio device 102. The audio device 600 may be implemented as or may otherwise include, for example, a computing device that executes stored instructions, and/or as hard-wired circuitry and/or as one or more processors that may execute stored computer-readable instructions. In the shown example, the audio device 600 may comprise or be connected to any of the following: one or more processors 601, storage 602 (which may comprise one or more computer-readable media such as memory), an external interface such as a network interface 603 (which may be configured to communicate with a network and/or the audio pipeline 103), a user interface 604, one or more microphones and/or associated elements 605 configured to detect sound and convert that detected sound into an audio signal such as analog audio signal or a digital audio signal, one or more digital signal processors 606 configured to implement one or more digital signal processing features of the audio device, one or more speakers and/or associated elements 607 configured to produce sound in response to a received audio signal such as an analog audio signal or a digital audio signal, and/or a local oscillator 608. The one or more processors 601 may be communicatively connected to any of the other elements 602-608 via one or more data buses and/or via one or more other types of connections.

The audio device 600 as shown in FIG. 6 is provided by way of example and not limitation, and may include additional, fewer, or alternate components. For example, the audio device 600 as shown in FIG. 6 may be identified with any suitable portion of any of the microphone assemblies as discussed herein, such as the microphone assemblies 200/300/400/500 as shown and described with respect to FIGS. 2A-2G, 3A-3C, 4A-4C, and 5A-5K for example. In such scenarios, the audio device 600 may not include the one or more speakers and/or associated elements 607, the user interface 604, etc. As another example, when the audio device 600 may be implemented as part of a microphone assembly 200/300/400/500 as discussed herein, the network interface 603 may comprise the connector 211 and associated circuitry, electronic components, etc. that facilitate the microphone assembly 200/300/400/500 receiving power and control data, transmitting digitized audio data, etc., as discussed herein.

The circuitry of elements 605 and 607 may be separate circuitry or a single instance of combined circuitry, as desired. In the shown example, the local oscillator 608 may provide a local asynchronous clock signal to the one or more processors 601, the circuitry of element 605, and the circuitry of element 607. However, the local asynchronous clock signal may be provided to any of the elements of FIG. 6, as desired. In an example, the one or more processors 601 may receive a signal from the local oscillator 608, and the one or more processors 601 may generate the asynchronous local clock based on the signal from the local oscillator 608. For example, the one or more processors 601 may comprise phase-locked loop (PLL) circuitry, and the signal from the local oscillator 608 may be an input to (e.g., for driving) the PLL circuitry.

The one or more processors 601 may be configured to execute instructions stored in storage 602. The instructions, when executed by the one or more processors 601, may cause the computing device (and thus the audio device) to perform any of the functionality described herein that may be performed by the audio device 600 (such as the audio device 101 or the audio device 102). For example, the one or more processors 601 may control the operation of any of the other elements 602-608 of the audio device 600, and/or may direct various signals (such as audio signals and/or clock signals) amongst the various elements 602-608 of the audio device.

Power may be provided to the audio device and/or to any of the elements of the audio device (e.g., any of the elements 601-608) as desired. While not explicitly shown, the audio device may include an internal battery and/or an external power connection, in addition to or instead of the connections as discussed herein.

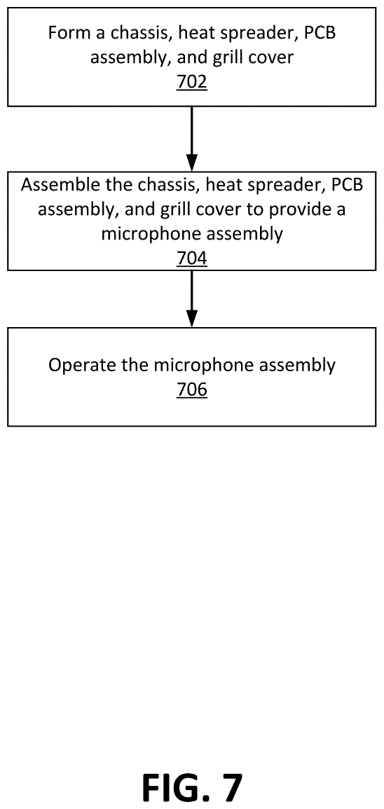

FIG. 7 illustrates an example flow chart of a process that may be performed to assemble a microphone assembly in accordance with one or more illustrative aspects described herein. The flow 700 may comprise a process flow that may be executed by and/or otherwise associated with any suitable automated, semi-automated, or manual process that may be performed to provide, for example, any of the microphone assemblies 200/300/400/500 as discussed herein. The flow 700 may thus may be implemented via the any suitable number and/or type of components, which may comprise portions of a manufacturing assembly line or other manufacturing process for example. The flow 700 may include alternate or additional processes that are not shown for purposes of brevity, and may be performed in a different order than those shown.

Flow 700 may begin by forming (block 702) the various components of the microphone assembly 200/300/400/500, for example, as discussed herein. Thus, although illustrated as a single block in FIG. 7, block 702 may represent separate processes, e.g. one per component. For example, block 702 may represent the formation of the chassis 202/402, the heat spreader 206/406, the PCB assembly 208/408, and the grill cover 204/404 as discussed herein with respect to the microphone assembly 200/300/400. As another example, the block 702 may represent the formation of the lower chassis 504.1, the upper chassis 504.1, the grill cover 504.2, the heat spreader 506, and the PCB assembly 508, as discussed herein with respect to the microphone assembly 500. The block 702 may alternatively represent the formation of any suitable components of any of the microphone assemblies 200/300/400/500.

The various components of the microphone assemblies 200/300/400/500 may be formed (block 702) in any suitable manner, including those discussed herein. For example, any of the chassis 202/402, the heat spreader 206/406, the PCB assembly 208/408, the grill cover 204/404, the lower chassis 504.1, the upper chassis 504.1, the grill cover 504.2, the heat spreader 506, and the PCB assembly 508, etc., may be produced via any suitable manufacturing processes, including known types such as casting, CNC (or other suitable types of) machining, extrusion, three-dimensional (3D) printing, plastic thermoforming, stamping, forming, etc.

The flow 700 may further comprise assembling (block 704) the various components of the microphone assemblies 200/300/400/500 to produce any of the assembled microphone assemblies as discussed herein. This may include, for instance, assembling the chassis 202/402, the heat spreader 206/406, the PCB assembly 208/408, and the grill cover 204/404 as discussed herein. Alternatively, this may include assembling the lower chassis 504.1, the upper chassis 504.1, the grill cover 504.2, the heat spreader 506, and the PCB assembly 508 as discussed herein. Again, this may include the use of retaining mechanisms, snap fit mechanisms, adhesives, thermal interface materials, etc., to assemble these components. In any event, upon being assembled, certain regions of the heat spreader 206/406/506 may be in thermal contact with one or more heat sources of the PCB assembly 208/408/508, such as the audio electronic components for example as discussed herein.

The process flow 700 may further comprise operating (block 706) the microphone assembly. This may include, for example, operating the microphone assembly in an active microphone configuration as discussed herein. Moreover, during operation, the heat spreader 206/406/506 may be configured to function as a heat path to thermally couple the heat sources of the microphone assembly to the grill cover 204/404/504.2, which functions as a heat sink for the heat sources, as discussed herein. The operation of the microphone assembly may comprise, for example, transmitting digitized audio data to another audio component via a wired or wireless connection, such as to a speaker for example as discussed herein.

An example microphone assembly may comprise a chassis, a heat spreader coupled to the chassis and thermally coupled to a heat source contained within the microphone assembly, and a thermally-conductive grill cover coupled to the heat spreader. The heat spreader may be configured to provide a heat path from the heat source to the thermally-conductive grill cover to enable the thermally-conductive grill cover to function as a heat sink for the heat source. The heat spreader may comprise a monolithic thermally-conductive material. The microphone assembly may further comprise a printed circuit board (PCB) assembly comprising an electronic component associated with a microphone, the heat source comprising the electronic component, and the PCB assembly may be disposed within the microphone assembly such that the electronic component is thermally coupled to a portion of the heat spreader. The heat spreader may comprise a thermally-conductive material having a lower thermal conductivity than the thermally-conductive grill cover. The heat spreader may comprise a heat pipe configured to distribute heat across the thermally-conductive grill cover. The chassis may comprise a mountable surface configured to be mounted to a ceiling, and the thermally-conductive grill cover may be disposed opposite to the mountable surface. The thermally-conductive grill cover may comprise perforations configured to enable sound to pass into the microphone assembly.

An example microphone assembly may comprise a chassis, a microphone, a thermally-conductive heat spreader configured to be thermally coupled to an audio integrated circuit (IC) associated with the microphone, and a thermally-conductive grill cover configured to be thermally coupled to the thermally-conductive heat spreader. The thermally-conductive heat spreader may be configured to provide a heat path from the audio IC to the thermally-conductive grill cover to enable the thermally-conductive grill cover to function as a heat sink for the audio IC. The thermally-conductive heat spreader may comprise a monolithic thermally-conductive material. The chassis may comprise a thermal insulator. The chassis may comprise a thermally-conductive material. The microphone assembly may further comprise a printed circuit board (PCB) assembly. The microphone and the audio IC may be mounted to the PCB assembly, and the audio IC may be thermally coupled to a portion of the thermally-conductive heat spreader. The thermally-conductive heat spreader may comprise a lower thermal conductivity than the thermally-conductive grill cover. The thermally-conductive heat spreader may comprise a heat pipe configured to distribute heat across the thermally-conductive grill cover. The chassis may comprise a mountable surface configured to be mounted to a ceiling, and the thermally-conductive grill cover may be configured to be disposed opposite to the mountable surface.

An example microphone assembly may comprise a grill cover assembly including a thermally-conductive upper chassis and a thermally-conductive grill cover, a lower chassis, and a heat spreader thermally coupled to the grill cover assembly and thermally coupled to a heat source contained within the microphone assembly. The heat spreader may be configured to provide a heat path from the heat source to the grill cover assembly to enable the thermally-conductive grill cover to function as a heat sink for the heat source. The lower chassis may comprise a thermally-conductive material, and the lower chassis and the grill cover assembly may be thermally isolated from one another. The lower chassis and the grill cover assembly may be thermally isolated from one another via an air gap. The thermally-conductive upper chassis and the thermally-conductive grill cover may have different thermal conductivities. The thermally-conductive upper chassis and the thermally-conductive grill cover may be separate components that are thermally coupled to one another via an adhesive.

In the foregoing specification, the present disclosure has been described with reference to specific exemplary examples thereof. Although the invention has been described in terms of a preferred example, those skilled in the art will recognize that various modifications, examples or variations of the invention can be practiced within the spirit and scope of the invention as set forth in the appended claims. The specification and drawings are, therefore, to be regarded in an illustrated rather than restrictive sense. Accordingly, it is not intended that the invention be limited except as may be necessary in view of the appended claims.

Unless otherwise specified, the use of the serial adjectives, such as, “first,” “second,” “third,” and the like that are used to describe components, are used only to indicate different components, which can be similar components. But the use of such serial adjectives is not intended to imply that the components must be provided in given order, either temporally, spatially, in ranking, or in any other way.

Also, while the terms “front,” “back,” “side,” and the like may be used in this specification to describe various example features and elements, these terms are used herein as a matter of convenience, for example, based on the example orientations shown in the figures and/or the orientations in typical use. Nothing in this specification should be construed as requiring a specific three dimensional or spatial orientation of structures in order to fall within the scope of the claims.

Although examples are described above, features and/or steps of those examples may be combined, divided, omitted, rearranged, revised, and/or augmented in any desired manner. Various alterations, modifications, and improvements will readily occur to those skilled in the art. Such alterations, modifications, and improvements are intended to be part of this description, though not expressly stated herein, and are intended to be within the spirit and scope of the disclosure. Accordingly, the foregoing description is by way of example only, and is not limiting.

1. A microphone assembly, comprising:
a chassis;
a heat spreader coupled to the chassis and thermally coupled to a heat source contained within the microphone assembly; and
a thermally-conductive grill cover coupled to the heat spreader,
wherein the heat spreader is configured to provide a heat path from the heat source to the thermally-conductive grill cover to enable the thermally-conductive grill cover to function as a heat sink for the heat source.

2. The microphone assembly of claim 1, wherein the heat spreader comprises a monolithic thermally-conductive material.

3. The microphone assembly of claim 1, further comprising:
a printed circuit board (PCB) assembly comprising an electronic component associated with a microphone, the heat source comprising the electronic component,
wherein the PCB assembly is disposed within the microphone assembly such that the electronic component is thermally coupled to a portion of the heat spreader.

4. The microphone assembly of claim 1, wherein the heat spreader comprises a thermally-conductive material having a lower thermal conductivity than the thermally-conductive grill cover.

5. The microphone assembly of claim 1, wherein the heat spreader comprises a heat pipe configured to distribute heat across the thermally-conductive grill cover.

6. The microphone assembly of claim 1, wherein the chassis comprises a mountable surface configured to be mounted to a ceiling, and
wherein the thermally-conductive grill cover is disposed opposite to the mountable surface.

7. The microphone assembly of claim 1, wherein the thermally-conductive grill cover comprises perforations configured to enable sound to pass into the microphone assembly.

8. A microphone assembly, comprising:
a chassis;
a microphone;
a thermally-conductive heat spreader configured to be thermally coupled to an audio integrated circuit (IC) associated with the microphone; and
a thermally-conductive grill cover configured to be thermally coupled to the thermally-conductive heat spreader,
wherein the thermally-conductive heat spreader is configured to provide a heat path from the audio IC to the thermally-conductive grill cover to enable the thermally-conductive grill cover to function as a heat sink for the audio IC.

9. The microphone assembly of claim 8, wherein the thermally-conductive heat spreader comprises a monolithic thermally-conductive material.

10. The microphone assembly of claim 8, wherein the chassis comprises a thermal insulator.

11. The microphone assembly of claim 8, wherein the chassis comprises a thermally-conductive material.

12. The microphone assembly of claim 8, further comprising:
a printed circuit board (PCB) assembly,
wherein the microphone and the audio IC are mounted to the PCB assembly, and
wherein the audio IC is thermally coupled to a portion of the thermally-conductive heat spreader.

13. The microphone assembly of claim 8, wherein the thermally-conductive heat spreader comprises a lower thermal conductivity than the thermally-conductive grill cover.

14. The microphone assembly of claim 8, wherein the thermally-conductive heat spreader comprises a heat pipe configured to distribute heat across the thermally-conductive grill cover.

15. The microphone assembly of claim 8, wherein the chassis comprises a mountable surface configured to be mounted to a ceiling, and
wherein the thermally-conductive grill cover is configured to be disposed opposite to the mountable surface.

16. A microphone assembly, comprising:
a grill cover assembly including a thermally-conductive upper chassis and a thermally-conductive grill cover;
a lower chassis; and
a heat spreader thermally coupled to the grill cover assembly and thermally coupled to a heat source contained within the microphone assembly,
wherein the heat spreader is configured to provide a heat path from the heat source to the grill cover assembly to enable the thermally-conductive grill cover to function as a heat sink for the heat source.

17. The microphone assembly of claim 16, wherein the lower chassis comprises a thermally-conductive material, and
wherein the lower chassis and the grill cover assembly are thermally isolated from one another.

18. The microphone assembly of claim 17, wherein the lower chassis and the grill cover assembly are thermally isolated from one another via an air gap.

19. The microphone assembly of claim 16, wherein the thermally-conductive upper chassis and the thermally-conductive grill cover have different thermal conductivities.

20. The microphone assembly of claim 16, wherein the thermally-conductive upper chassis and the thermally-conductive grill cover are separate components that are thermally coupled to one another via an adhesive.
